(19) United States
(12) Patent Application Publication
(10) Pub. No.: US 2024/0178102 A1
(43) Pub. Date: May 30, 2024

(54) PACKAGE INCLUDING BACKSIDE CONNECTOR AND METHODS OF FORMING THE SAME

(71) Applicant: Taiwan Semiconductor Manufacturing Company Limited, Hsinchu (TW)

(72) Inventors: Chun-Ti LU, Hsinchu (TW); Hao-Yi TSAI, Hsinchu (TW); Chiahung LIU, Hsinchu (TW); Ken-Yu CHANG, Hsinchu (TW); Tzuan-Horng LIU, Taoyuan (TW); Chih-Hao CHANG, Hsinchu (TW); Bo-Jiun LIN, Hsinchu (TW); Shih-Wei CHEN, Hsinchu (TW); Pei-Rong NI, Chiayi (TW); Hsin-Wei HUANG, Hsinchu (TW); Zheng GangTsai, Tainan (TW); Tai-You LIU, Hsinchu (TW); Steve SHIH, Taichung (TW); Yu-Ting HUANG, Hsinchu (TW); Steven SONG, Hsinchu (TW); Yu-Ching WANG, Kaohsiung (TW); Tsung-Yuan YU, Taipei (TW); Hung-Yi KUO, Taipei (TW); CHung-Shi LIU, Hsinchu (TW); Tsung-Hsien CHIANG, Hsinchu (TW); Ming Hung TSENG, Miaoli (TW); Yen-Liang LIN, Taichung (TW); Tzu-Sung HUANG, Tainan (TW); Chun-Chih CHUANG, Taichung (TW)

(21) Appl. No.: 18/304,638

(22) Filed: Apr. 21, 2023

Related U.S. Application Data
(60) Provisional application No. 63/429,145, filed on Nov. 30, 2022.

(51) Int. Cl. H01L 23/48; H01L 21/56; H01L 23/00; H01L 23/31; H01L 23/498

(52) U.S. Cl. CPC H01L 23/481; H01L 21/565; H01L 23/3128; H01L 23/49816; H01L 24/05; H01L 24/13; H01L 24/48; H01L 2224/0231; H01L 2224/0401; H01L 2224/05647; H01L 2224/13111; H01L 2224/48227; H01L 2924/1436

(57) ABSTRACT

A package includes a frontside redistribution layer (RDL) structure, a semiconductor die on the frontside RDL structure, and a backside RDL structure on the semiconductor die including a first RDL, and a backside connector extending from a distal side of the first RDL and including a tapered portion having a width that decreases in a direction away from the first RDL, wherein the tapered portion includes a contact surface at an end of the tapered portion. A method of forming the package may include forming the backside redistribution layer (RDL) structure, attaching a semiconductor die to the backside RDL structure, forming an encapsulation layer around the semiconductor die on the backside RDL structure, and forming a frontside RDL structure on the semiconductor die and the encapsulation layer.

### RELATED APPLICATIONS

This application claims priority from U.S. Provisional Application Ser. No. 63/429,145 entitled “Package Including Backside Connector And Methods Of Forming The Same,” filed on Nov. 30, 2022, the entire contents of which are incorporated herein by reference for all purposes.

### BACKGROUND

Packages (e.g., integrated fan-out (InFO) packages) are commonly used in semiconductor devices such as advanced mobile products. A typical package may have a package-on-package configuration in which an upper package may be stacked on a bottom package. The upper package may include a memory device such as a dynamic random access memory (DRAM) device. This configuration may require customized DRAM and turnkey business mode for DRAM pre-stacking. Alternatively, the package may include a “bottom” or “only” configuration that may omit the upper package. This configuration may provide a versatile package without the need for customization.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package according to one or more embodiments.

FIG. 1B is a detailed view of a highlighted portion of the package according to one or more embodiments.

FIG. 1C is a detailed perspective view of the backside connector according to one or more embodiments.

FIG. 2A is a vertical cross-sectional view of an intermediate structure including the first redistribution layer (RDL), according to one or more embodiments.

FIG. 2B is a vertical cross-sectional view of an intermediate structure including the backside RDL structure and through vias (TVs), according to one or more embodiments.

FIG. 2C is a vertical cross-sectional view of an intermediate structure including the semiconductor die on the backside RDL structure, according to one or more embodiments.

FIG. 2D is a vertical cross-sectional view of an intermediate structure including the encapsulant layer on the backside RDL structure, according to one or more embodiments.

FIG. 2E is a vertical cross-sectional view of an intermediate structure including the encapsulant layer after performing the planarization process, according to one or more embodiments.

FIG. 2F is a vertical cross-sectional view of an intermediate structure including the frontside RDL structure, according to one or more embodiments.

FIG. 2G is a vertical cross-sectional view of an intermediate structure on a frame mount, according to one or more embodiments.

FIG. 3 is a vertical cross-sectional view of a first alternative configuration of the package, according to one or more embodiments.

FIG. 4 is a vertical cross-sectional view of a second alternative configuration of the package, according to one or more embodiments.

FIG. 5 is a vertical cross-sectional view of a third alternative configuration of the package, according to one or more embodiments.

FIG. 6 is a vertical cross-sectional view of a fourth alternative configuration of the package, according to one or more embodiments.

FIG. 7 is a vertical cross-sectional view of a fifth alternative configuration of the package, according to one or more embodiments.

FIG. 8A is a vertical cross-sectional view of an intermediate structure including the backside RDL structure bonded to the carrier substrate, according to one or more embodiments.

FIG. 8B is a vertical cross-sectional view of an intermediate structure including the semiconductor die and frontside RDL structure, according to one or more embodiments.

FIG. 9 is a vertical cross-sectional view of a sixth alternative configuration of the package, according to one or more embodiments.

FIG. 10A is a vertical cross-sectional view of an intermediate structure including the first polymer layer including dark material bonded to the carrier substrate, according to one or more embodiments.

FIG. 10B is a vertical cross-sectional view of an intermediate structure including the backside RDL structure bonded to the carrier substrate, according to one or more embodiments.

FIG. 10C is a vertical cross-sectional view of an intermediate structure including the semiconductor die and frontside RDL structure, according to one or more embodiments.

FIG. 11 is a vertical cross-sectional view of a seventh alternative configuration of the package, according to one or more embodiments.

FIG. 12 is a vertical cross-sectional view of an eighth alternative configuration of the package, according to one or more embodiments.

FIG. 13 is a vertical cross-sectional view of the backside connector, according to one or more embodiments.

FIG. 14 is a vertical cross-sectional view of an alternative configuration of the backside connector, according to one or more embodiments.

FIG. 15 is a flow chart illustrating a method of forming a package, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A related package without backside redistribution layers (RDLs) may be unable to support commodity Low-Power Double Data Rate dynamic random access memory (LPDDR DRAM) due to its ball map & routing capability. In addition, a related package with backside RDLs may suffer from backside joint pad damage (e.g., copper dendrite; crack in a solder intermetallic compound (IMC)) and/or pad/polyimide delamination post temperature cycling (e.g., TCG500).

The related package may also include a backside enhancement layer (BEL) on a backside of the package. Concave holes (e.g., cavities; laser-drilled holes) may be formed in the BEL for pre-solder landing. However, the concave holes potentially have environmental contamination (e.g., mobile ion). This contamination may expedite copper dendrite formation and lead to an electrical shortage failure. In particular, a backside RDL layer may serve not only as DRAM joint pad but may also be treated as a routing layer, and the 20 μm space in the backside RDL layer may not be far enough to gain a copper dendrite bridge window.

Various embodiments disclosed herein may include a package having a backside connector that may eliminate the problems of typical packages. The backside connector may extend from a first RDL of a backside RDL structure and include a tapered portion (e.g., via) having a width that decreases in a direction away from the first RDL (e.g., away from the frontside RDL structure). The backside connector may also include a contact surface at an end of the tapered portion.

The backside connector may include, for example, a backside underbump metallization (BUBM) (e.g., a seed layer) to enhance polymer (e.g., polyimide) adhesion, and thereby avoid the use of a laser drill to form a DRAM joint. The BUBM may help to enlarge a reliability window in the package. The polymer layer may include a sidewall with taper angle for stress relaxation. The RDLs may be formed by electrochemical plating (ECP) to ensure copper RDL step coverage along the tapered polymer (e.g., polyimide) sidewall.

In one or more embodiments, the package with BUBM may include a backside first polymer layer (BS PM1) including dark material (e.g., dark polymer material, dark molding material, etc.) for laser marking. In one or more embodiments, the BUBM may be formed with or without a routing layer under different RDL layer counts combination. In one or more embodiments, the package with BUBM may have either a bottom configuration or package-on-package configuration. In one or more embodiments, the BUBM may include an exposed BUBM (e.g., pillar structure)

In one or more embodiments, the package may include a UBM structure at dual sides (e.g., frontside and backside) of the package. The UBM structure may be used, for example, for a printed circuit board (PCB) joint only or a DRAM joint only (e.g., without a routing function). The package may include a thin polymer (e.g., polyimide) layer with dye (i.e., no filler) at a backside of the package, for laser marking. Further, the package may include a convex pre-solder layer on the backside of the package.

The package may provide several advantages and benefits. For example, the package may be fully leveraged for use with a proven “package-on-package” production process and design rule. The package may provide a tunable package warpage by RDL and polymer (e.g., polyimide) layer thickness optimization to fulfill various kinds of PKG warpage requirements. The package may eliminate the need for laser drill process and thereby eliminate a deleterious effect (e.g., heat affected zone (HAZ) effect) on adhesion between the BEL, polymer and/or the backside first RDL. Further, the package may eliminate the need for a cavity in a backside layer and thereby minimize a risk of environmental contamination. The package may also mitigate stress that may result in crack in the backside RDL (e.g., connected to a DRAM ball).

In at least one embodiment, the package may include the UBM on both the backside and the front side of the package. The package may avoid the use of BEL material. The package may optimize a thickness of the backside first RDL and/or a thickness of the backside second polymer layer. The package may provide a relatively thicker UBM (e.g., having a UBM thickness that is greater than that of a typical package).

In at least one embodiment, a backside post-passivation interconnect (PPI) loop may include at least three metal layers. The second RDL and third RDL may be for design routing and first RDL may be for providing a DRAM joint (i.e., no routing). The first RDL (i.e., which may include a pad) may, for example, have a shape like a sunhat. The first RDL may also have a height that is greater than a height of first polymer layer with a step Z, where Z may be greater than about 0.1 μm. Further, a barrier layer may be formed at the interface between a wing of the first RDL and the first polymer layer.

The package may further include a layer for laser marking (LMK) on the backside RDL. The marking may be made, for example by using a focused ion beam (FIB) laser. The layer may be without filler and may form a readable marking letter by void mode within it.

In at least one embodiment, the backside connector of the package may include a pillar structure on the tapered portion of the backside connector. The pillar structure may include a molded pillar structure having a thickness of greater than about 20 μm. The pillar structure may include, for example, one or more copper pillars and backside RDLs. The copper pillars may help to achieve a more robust structure with a low cost and a low cycle time.

The pillar structure (e.g., copper pillar) may be formed before the backside RDLs. Thus, the pillar structure may be formed in a manner similar to a typical package with through via (TV) as a first layer. A thickness of the pillar structure with molding can be used to tune component warpage in the package. The package may also include an easily recognized marking on a molding material instead of a polyimide layer that may be transparent. The features of the novel package may help the package eliminate the backside joint pad damage (e.g., a copper crack) and copper/polymer (e.g., polyimide) delamination that may occur in a typical package post reliability assessment (RA).

The package may provide other advantages over the typical package. The package may avoid the need for a laser drill which may help to eliminate thermal degradation of interface adhesion, and thereby help to reduce cycle time. The package may also avoid the need for a backside enhancement layer (BEL), which may reduce a risk of a crack in the BEL, and thereby reduce cycle time and improve reliability. Further, a thickness of the pillar structure (e.g., copper pillar) can effectively serve as a tuning knob for warpage control, and thereby provide an improved flexibility. The package may provide a decreased risk of shrinkage and/or void formation in a die attach film (DAF) by utilizing a backside first RDL having a reduced thickness (e.g., from about 8.5 μm down to about 4.5 μm), and thereby provide an improved reliability. The package may also avoid the need for additional bond/de-bond steps for backside underbump metallization (BUBM) formation, and thereby help to reduce cycle time.

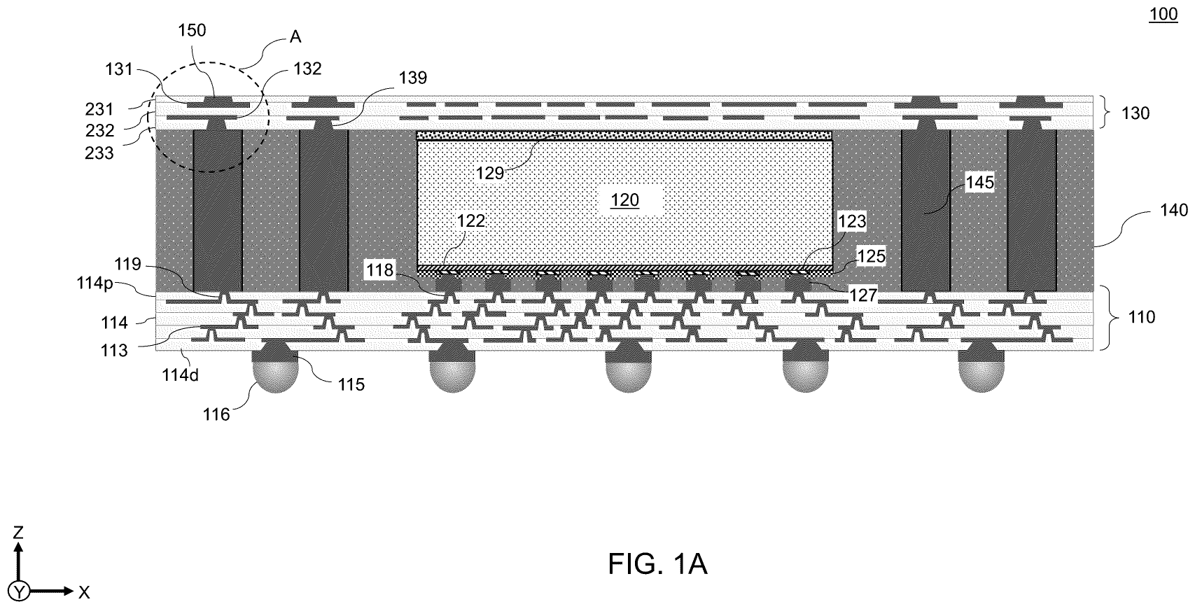

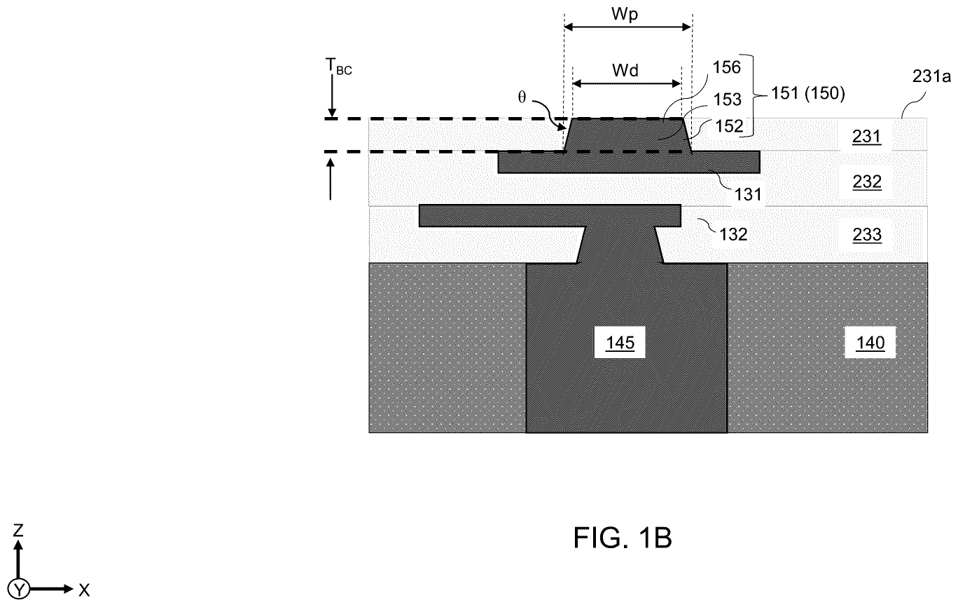

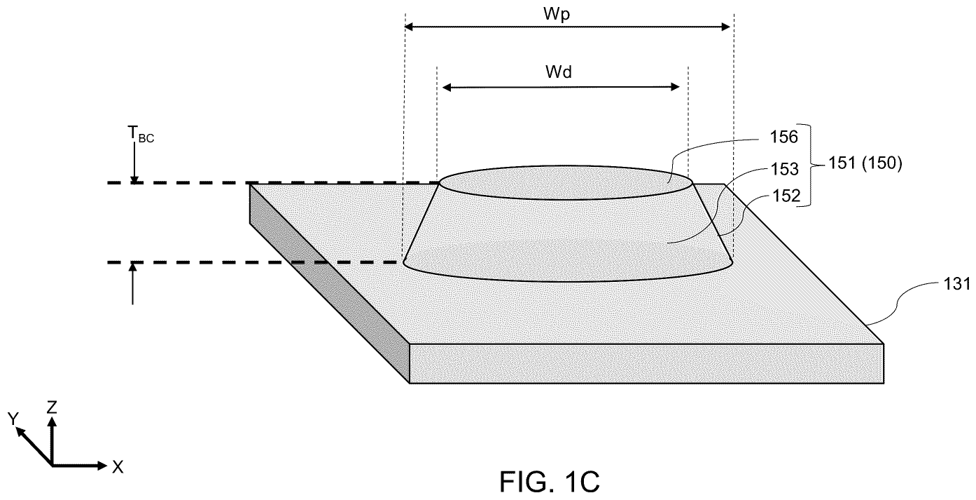

FIG. 1A is a vertical cross-sectional view of a package 100 according to various embodiments. FIG. 1B is a detailed view of a highlighted portion A of the package 100 according to one or more embodiments. FIG. 1C is a detailed view of the backside connector 150 according to one or more embodiments.

It should be noted that the terms “proximal” and “distal” may be used at times to describe elements of the package 100. These terms are used with reference to a central portion (e.g., a portion including a semiconductor die 120) of the package 100 in the z-direction (first vertical direction vd1). Thus, for example, a “proximal” side of a redistribution layer may refer to a side of the redistribution layer that is nearest the central portion in the z-direction, and a “distal” side of the redistribution layer may refer to a side of the redistribution layer that is farthest away from the central portion in the z-direction.

As illustrated in FIG. 1A, the package 100 may include a frontside RDL structure 110, one or more semiconductor dies 120 (e.g., silicon die) on the frontside RDL structure 110, and a backside RDL structure 130 on the semiconductor die 120. The backside RDL structure 130 may include a first RDL 131, and a backside connector 150 extending from the first RDL 131 in a first direction away from the first RDL 131 (e.g., away from the frontside RDL structure 110). The backside connector 150 may include a tapered portion 151 having a width that decreases in the first direction. The tapered portion 151 may include a contact surface 156 at an end of the tapered portion 151. The contact surface 156 may serve as a joint pad for mounting an upper package on the package 100. Alternatively, the tapered portion 151 may include a via, in which case a pillar structure (e.g., copper pillar) may be connected to a distal end of the via.

In at least one embodiment, the frontside RDL structure 110 may include a plurality of polymer layers 114 and a plurality of redistribution layers 113 stacked alternately. The number of the polymer layers 114 and/or the number of redistribution layers 113 in the frontside RDL structure 110 is not limited by the disclosure.

In at least one embodiment, the polymer layers 114 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 113 may include conductive materials. The conductive materials may include metal such as copper, aluminum, nickel, titanium, a combination thereof or other suitable metals.

The redistribution layers 113 may include a seed layer (not shown) and an upper metal layer formed thereon (not shown). The seed layer may include a metal seed layer such as a copper seed layer. In some embodiments, the seed layer may include a first metal layer such as a titanium layer and a second metal layer such as a copper layer over the first metal layer. The upper metal layer may include copper or other suitable metals.

The redistribution layers 113 may include metallic connection structures, i.e., metallic structures that provide electrical connection between nodes in the structure. The redistribution layers 113 may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 113 may include copper, nickel, or copper and nickel. Other suitable metallic fill materials are within the contemplated scope of disclosure. The thickness of the metallic fill material that is deposited for each redistribution layers 113 may be in a range from 2 microns to 40 microns, such as from 4 microns to 10 microns, although lesser or greater thicknesses may also be used.

In at least one embodiment, the redistribution layers 113 may include a plurality of traces (lines) and a plurality of vias connecting the plurality traces to each other. The traces may be respectively located on the polymer layers 114, and may extend in the x-direction (first horizontal direction hd1) and y-direction (second horizontal direction hd2) on the top surface of the polymer layers 114.

In some embodiments, the polymer layers 114 in the frontside RDL structure 110 may include a distal polymer layer 114d. The distal polymer layer 114d may include an under-bump metallurgy (UBM) layer 115. The UBM layer 115 may include a metal such as copper, aluminum, nickel, titanium, a combination thereof or other suitable metals. A portion of the UBM layer 115 may be disposed on an underside of the distal polymer layer 114d and serve as a joint pad. A solder ball 116 may be disposed on the UBM layer 115 and used to mount the package 100 onto a substrate such as a printed circuit board (PCB). The solder ball 116 may include a standard solder material (e.g., SAC304 or SAC405). The solder material may include a lead-free solder material. The solder material may include tin and one or more other elements such as silver, indium, antimony, bismuth, zinc, etc. Other suitable solder materials are within the contemplated scope of disclosure. The UBM layer 115 may alternatively include a micro bump for connecting to an integrated passive device (IPD) to the frontside RDL structure 110.

The polymer layers 114 in the frontside RDL structure 110 may also include a proximal polymer layer 114p. The proximal polymer layer 114p may include one or more vias 118 that may serve as frontside bonding pads for connecting the semiconductor die 120 to the frontside RDL structure 110. The proximal polymer layer 114p may also include one or more vias 119 that may serve as frontside bonding pads for connecting one or more through vias (TVs) to the frontside RDL structure 110. The vias 119 may have a size (e.g., diameter, width in the x-direction, etc.) that is greater than a size of the vias 118. The vias 118 and vias 119 may be formed concurrently with the redistribution layers 113, and may include a metal such as copper, aluminum, nickel, titanium, a combination thereof or other suitable metals.

The semiconductor die 120 may be mounted on the proximal polymer layer 114p of the frontside RDL structure 110. The semiconductor die 120 may include, for example, a semiconductor chip or chiplet for a high performance computing (HPC) application, an artificial intelligence (AI) application, and a 5G cellular network application. In at least one embodiment, the semiconductor die 120 may include a logic die (e.g., mobile application processor, microcontroller, etc.), or a memory die (e.g., dynamic random access memory (DRAM) die, a Wide I/O die, a M-RAM die, a R-RAM die, a NAND die, static random access memory (SRAM), etc.). In at least one embodiment, the semiconductor die 120 may include a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

The semiconductor die 120 may include, for example, an active region 122. The active region 122 may include a front end of line (FEOL) region including electronic circuitry including various electronic devices (e.g., transistors, resistors, etc.). In particular, the FEOL region may include one or more logic circuits including logic devices (e.g., logic gates) and/or one or more memory circuits including memory devices (e.g., volatile memory (VM) devices and/or non-volatile memory (NVM) devices). The active region 122 may also include a back end of line (BEOL) region that may include interlayer dielectric having a plurality of dielectric layers. The dielectric layers may include, for example, SiO₂, a dielectric polymer or other suitable dielectric material. The interlayer dielectric may include one or more metal interconnect structures formed therein. The metal interconnect structures may include metal traces and metal vias formed in the dielectric layers and provide an electrical connection to the electronic circuitry in the FEOL region.

The semiconductor die 120 may also include one or more semiconductor die contact pads 123 on a surface of the active region 122. The semiconductor die contact pads 123 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The semiconductor die 120 may also include a semiconductor die passivation layer 125 on the surface of the semiconductor die active region 122. In particular, the semiconductor die passivation layer 125 may at least partially cover the semiconductor die contact pads 123. The semiconductor die passivation layer 125 may include silicon oxide, silicon nitride, low-k dielectric materials such as carbon-doped oxides, extremely low-k dielectric materials such as porous carbon doped silicon dioxide, a combination thereof or other suitable material. The semiconductor die contact pads 123 may be exposed through openings in the passivation layer 125.

The package 100 may also include semiconductor die bonding pads 127 that contact the semiconductor die contact pads 123 through the openings in the passivation layer 125. The semiconductor die bonding pads 127 may have one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. The semiconductor die 120 may be connected to the frontside RDL structure 110 by connecting the semiconductor die bonding pads 127 to the vias 118 (e.g., frontside RDL bonding pads in the proximal polymer layer 114p.

An adhesive layer 129 may be located on a side of the semiconductor die 120 opposite the active region 122. The adhesive layer 129 may include, for example, an epoxy adhesive, silicone adhesive, die attach film (DAF), or other suitable adhesives.

As further illustrated in FIG. 1A, one or more through vias (TVs) 145 may be located on the frontside RDL structure 110. The TVs 145 may be connected to the vias 119 (e.g., frontside bonding pads) in the proximal polymer layer 114p. The TVs 145 may have a columnar or cylindrical shape (e.g., circular cylinder shape). The TVs 145 may have a diameter (e.g., width) in the x-direction that is greater than a width of the vias 119. The TVs 145 may have a height in the z-direction that is substantially the same as a height of the adhesive layer 129 on the semiconductor die 120. That is, a surface of the TVs 145 may be substantially coplanar with a surface of the adhesive layer 129. The TVs 145 may have one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package 100 may also include an encapsulant layer 140 on the frontside RDL structure 110. The encapsulant layer 140 may laterally (e.g., in the x-direction and y-direction) encapsulate the semiconductor die 120 and the TVs 145. The encapsulant layer 140 may also be located on and around the semiconductor die bonding pads 127 between the semiconductor die 120 and the frontside RDL structure 110. A surface of the encapsulant layer 140 may be substantially coplanar with a surface of the TVs 145 and a surface of the adhesive layer 129. In some embodiments, the encapsulant layer 140 may include a molding compound, a molding underfill, a resin (such as an epoxy resin), or a combination thereof, or other suitable encapsulant materials.

The backside RDL structure 130 may be disposed on the surface of the encapsulant layer 140, the surface of the TVs and the surface of the adhesive layer 129. The backside RDL structure 130 may be adhered to the semiconductor die 120 by the adhesive layer 129.

The backside RDL structure 130 may include a first polymer layer 231 and a first RDL 131 on a surface of the first polymer layer 231. The backside RDL structure 130 may also include a second polymer layer 232 on the surface of the first polymer layer 231 and a second RDL 132 on a surface of the second polymer layer 232. The backside RDL structure 130 may also include a third polymer layer 233 on the second polymer layer 232. The first polymer layer 231, second polymer layer 232 and third polymer layer 233 may include, for example, polyimide (PI), epoxy resin, acrylic resin, phenol resin, benzocyclobutene (BCB), polybenzoxazole (PBO), or any other suitable polymer-based dielectric material. The first RDL 131 and second RDL 132 may include conductive materials. The conductive materials include metal such as copper, aluminum, nickel, titanium, a combination thereof or other suitable metal materials.

The third polymer layer 233 may contact the surface of the surface of the encapsulant layer 140, the surface of the TVs and the surface of the adhesive layer 129. The third polymer layer 233 may also include backside bonding pads 139 having a distal end connected to the second RDL 132 and a proximal end connected to the TVs 145. The backside bonding pads 139 may include a material similar to that of the vias 119 (e.g., frontside bonding pads).

Referring to FIG. 1B, the backside connector 150 may extend in the z-direction from the first RDL 131 (e.g., away from the encapsulation layer 140). As illustrated in FIG. 1B, the backside connector 150 may include a tapered portion 151. The tapered portion 151 may include a contact surface 156 at an end (e.g., distal end) of the tapered portion 151. The tapered portion 151 may also include a connector plate 153 and a tapered sidewall 152 on the connector plate 153.

The backside connector 150 may be formed in an opening in the first polymer layer 231, and the opening may have a tapered sidewall including a taper angle θ (e.g., the angle between the z-direction and the tapered sidewall 152 of the tapered portion 151). In at least one embodiment, the taper angle θ may be in a range from 30° to 80°. The taper angle θ may help to relax a stress on the backside connector 150 and first RDL 131. In addition, as will be discussed later, the first RDL 131 may be formed by electrochemical plating (ECP) which may help to ensure RDL step coverage along the tapered sidewall of the opening in the first polymer layer 231.

The tapered portion 151 may have a shape corresponding to a shape of the opening in the first polymer layer 231. The tapered portion 151 may have a proximal end connected to a distal side of the first RDL 131. The proximal end of the tapered portion 151 may have a width Wp. The connector plate 153 of the tapered portion 151 may extend into the first polymer layer 231 to a surface 231a of the first polymer layer 231. The tapered portion 151 may also include the tapered sidewalls 152 around the periphery of the connector plate 153. The connector plate 153 may have a thickness in the z-direction that is substantially the same as a thickness of the first polymer layer 231. In at least one embodiment, the thickness of the connector plate 153 (e.g., and the thickness of the first polymer layer 231) may be in a range from 5 μm to 30 μm.

The tapered portion 151 of the backside connector 150 may also include a contact surface 156 at an end of the tapered portion 151. In particular, the contact surface 156 may be formed at a distal end of the tapered portion 151 opposite the proximal end. The contact surface 156 of the tapered portion 151 may be substantially coplanar with the surface 231a of the first polymer layer 231. The contact surface 156 may have a width Wd which is less than the width Wp of the proximal end of the tapered portion 151. In at least one embodiment, the width Wd of the contact surface 156 may be less than 90% of the width Wp of the proximal end of the tapered portion 151. In at least one embodiment, the width Wd of the contact surface 156 may be greater than 50% of the width Wp of the proximal end. The width of the tapered portion 151 may decrease continuously from the width Wp to the width Wd. The width of the tapered portion 151 may alternatively decrease in steps. That is, a sidewall of the tapered portion 151 may have a straight-line configuration or a stepped configuration.

Referring to FIG. 1C, the connector plate 153 may be continuously and integrally formed as a unit with the first RDL 131. The connector plate 153 may have a shape of a bottom portion of a solid conical cylinder. A cross-section of the solid conical cylinder may include a circular cross-section, although other shapes (e.g., oval) are within the scope of this disclosure. The contact surface 156 of the tapered portion 151 may constitute a joint pad. The joint pad may serve as underbump metallization (UBM) for a solder bump or solder ball. Thus, for example, an upper package may be mounted on the package 100 and electrically connected to the package 100 through one or more solder balls (e.g., a ball grid array (BGA)) mounted on one or more joint pads on backside connectors 150, respectfully.

The backside connector 150 may allow the package 100 to provide a tunable package warpage. In particular, a thickness of the connector plate 153, a thickness of the first RDL 131, and/or a thickness of the first polymer layer 231 may be optimized to fulfill various kinds of package warp requirements. The backside connector 150 may also eliminate the need for a backside enhancement layer (BEL) with cavities formed by a laser drill. This may minimize a risk of environmental contamination and eliminate a deleterious effect on adhesion with the backside RDL structure 130. The backside connector 150 may also help to mitigate stress may result in crack in the first RDL 131 of the backside RDL structure 130.

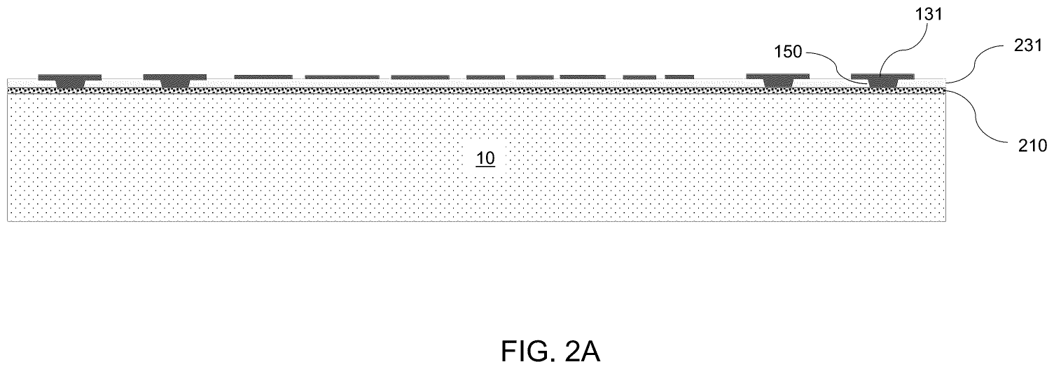

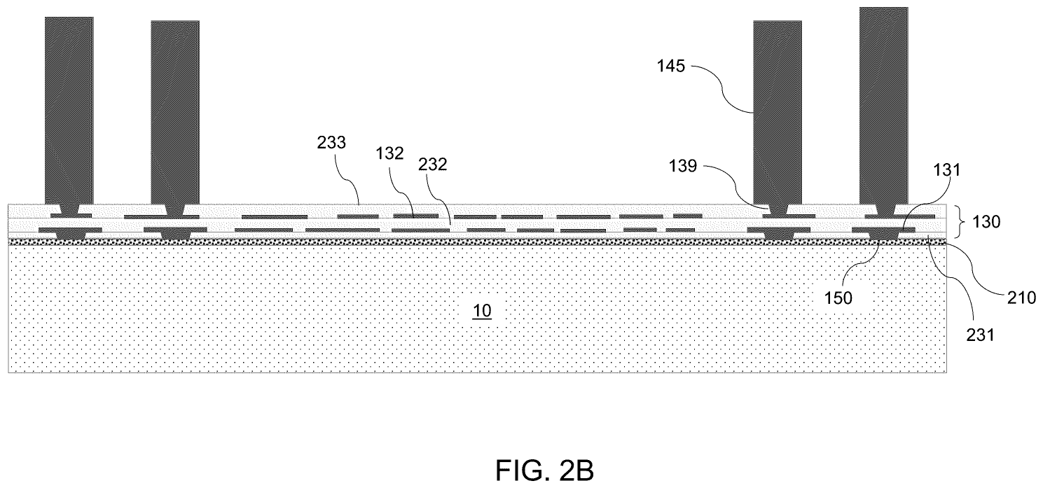

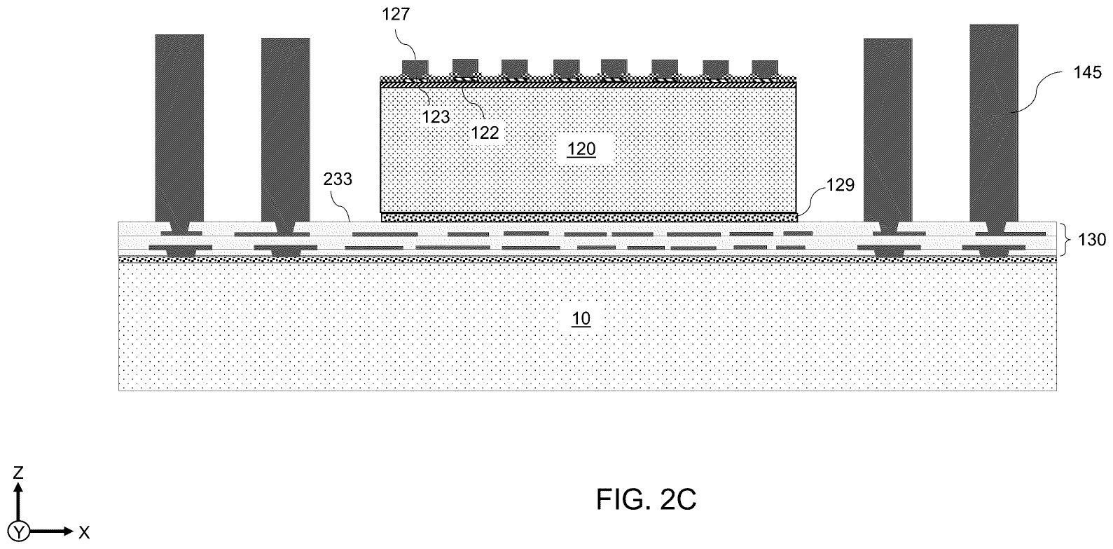

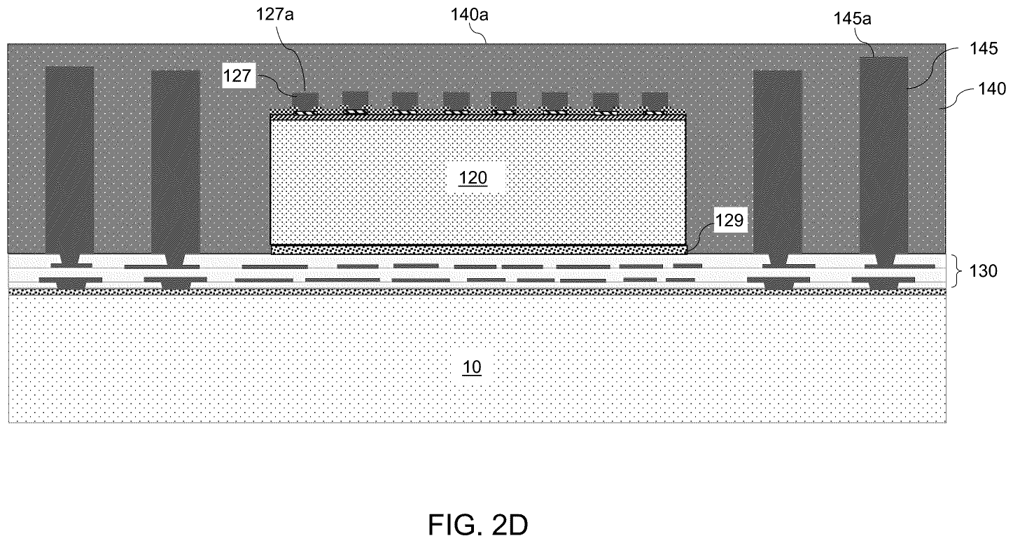

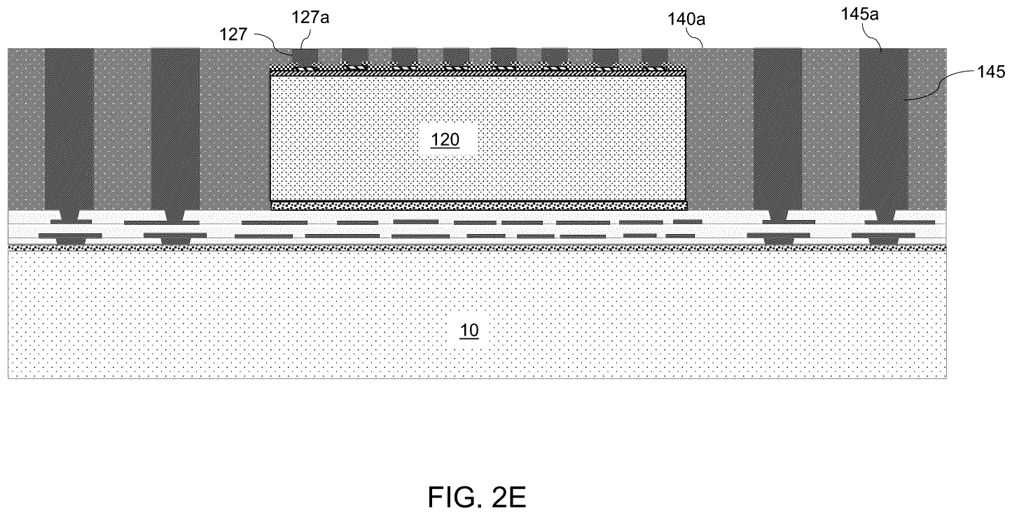

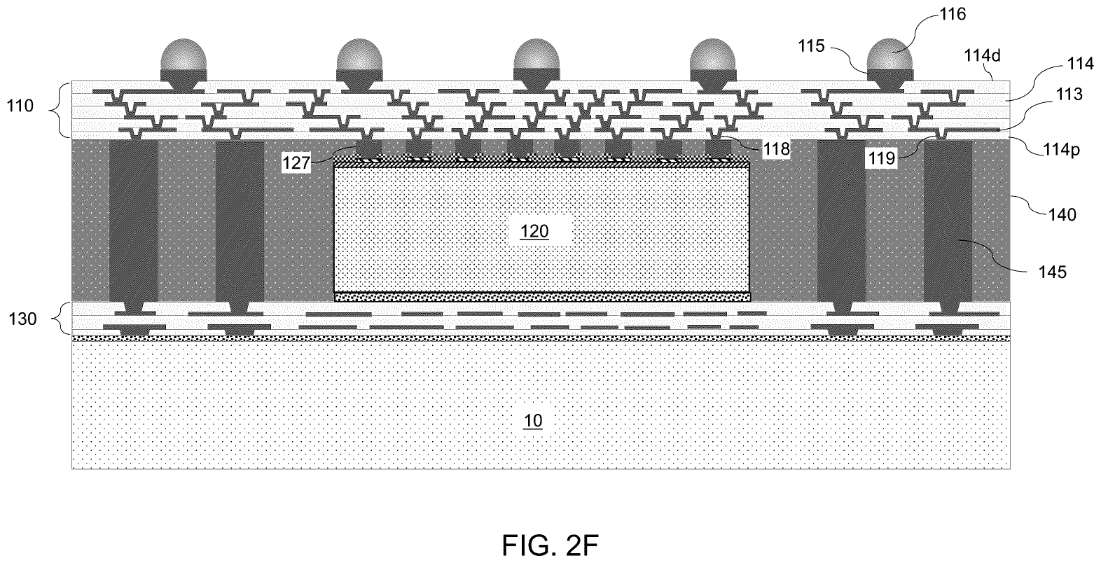

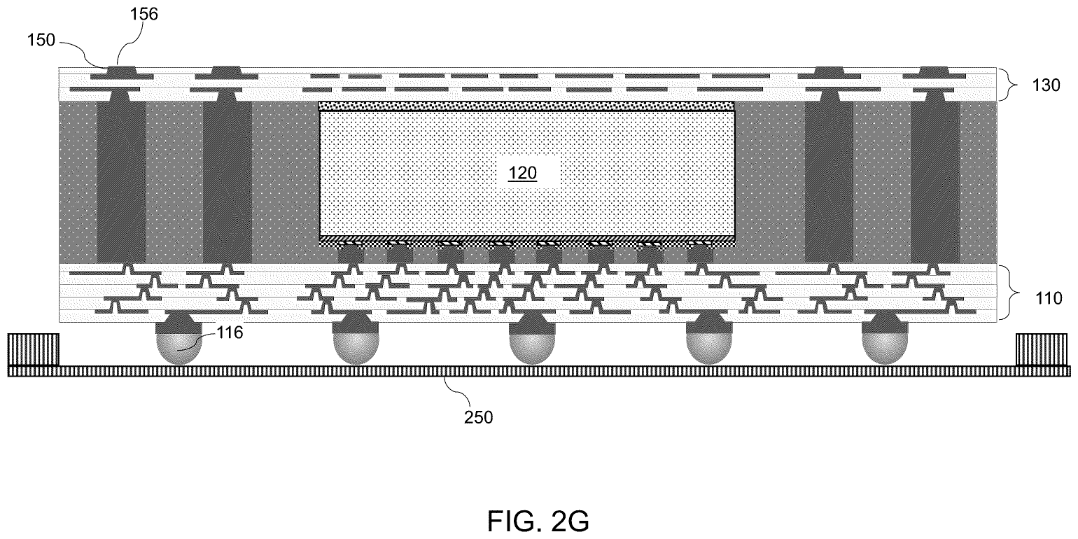

FIGS. 2A-2F are vertical cross-sectional views of various intermediate structures in a method of forming the package 100, according to one or more embodiments. In particular, FIG. 2A is a vertical cross-sectional view of an intermediate structure including the first RDL 131, according to one or more embodiments.

As illustrated in FIG. 2A, the first polymer layer 231 may be formed on an adhesive layer 210 on an upper surface of a carrier substrate 10. The carrier substrate 10 may include a semiconductor wafer (e.g., circular wafer or a rectangular wafer) or glass substrate. The lateral dimensions (such as the diameter of a circular wafer or a side of a rectangular wafer) of the carrier substrate 10 may be in a range from 100 mm to 500 mm, such as from 200 mm to 400 mm, although lesser and greater lateral dimensions may also be used. The carrier substrate 10 may be transparent or opaque. The thickness of the carrier substrate 10 may be sufficient to provide mechanical support to the package 100. For example, the thickness of the carrier substrate 10 may be in a range from 60 microns to 1 mm, although lesser and greater thicknesses may also be used.

The adhesive layer 210 may be applied to the upper surface of the carrier substrate 10. The adhesive layer may include a light-to-heat conversion (LTHC) layer or may include a thermally decomposing adhesive material. The LTHC layer may include a solvent-based coating applied using a spin coating method. The LTHC layer may form a layer that converts ultraviolet light to heat such that the LTHC layer loses adhesion. Alternatively, the adhesive layer (not shown) may include a thermally decomposing adhesive material. For example, the adhesive layer may include an acrylic pressure-sensitive adhesive that decomposes at an elevated temperature. The debonding temperature of the thermally decomposing adhesive material may be in a range from 150° ° C. to 400° C. Other suitable thermally decomposing adhesive materials that decompose at other temperatures are within the contemplated scope of disclosure.

The first polymer layer 231 may be formed on the adhesive layer 210. The first polymer layer 231 may be formed, for example, by deposition. In particular, the first polymer layer 231 may be deposited by chemical vapor deposition (CVD), plasma enhanced chemical vapor deposition (PECVD), physical vapor deposition (PVD), spin coating, lamination or other suitable deposition technique.

Openings may be formed in the first polymer layer 231 for the subsequent formation of the backside connectors 150. The openings may extend through an entirety of the first polymer layer 231 so as to expose a surface of the adhesive layer 231 through the openings. The openings may be formed, for example, by a photolithographic process including forming a patterned photoresist layer, and etching (e.g., wet etching, dry etching, etc.) the first polymer layer 231 through the patterned photoresist layer. The etching may be performed, for example, in one or more etching steps.

The first RDL 131 and backside connectors 150 (e.g., tapered portion 151) may then be formed on a surface of the first polymer layer 231 and in the openings in the first polymer layer 231. The first RDL 131 and backside connectors 150 may be formed concurrently in the same forming step. The first RDL 131 and backside connectors 150 may be formed by an electroplating process in which a seed layer (not shown) is first formed in the openings and the surface of the first polymer layer 231. The seed layer (e.g., metallic seed layer) may be formed, for example, by depositing the seed layer in a deposition process such as CVD, PECVD, PVD, spin coating, lamination or other suitable deposition technique, by applying and patterning a photoresist layer over the seed layer to form a pattern of openings through the photoresist layer, by electroplating a metallic fill material (such as copper, nickel, or a stack of copper and nickel), by removing the photoresist layer (for example, by ashing), and by etching portions of the seed layer located between the electroplated metallic fill material portions. The metal material electroplated on the seed layer may form the first RDL 131 and backside connectors 150. The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

FIG. 2B is a vertical cross-sectional view of an intermediate structure including the backside RDL structure 130 and TVs 145, according to one or more embodiments. As illustrated in FIG. 2B, the second polymer layer 232, second RDL 132 and third polymer layer 233 may be formed successively on the first polymer layer 231 and over the first RDL 131. The formation of the second polymer layer 232, second RDL 132 and third polymer layer 233 may be in a manner described above with respect to the first polymer layer 231 and first RDL 131. A thickness of the second RDL 132 may be substantially the same as a thickness of the first RDL 131. A thickness of the second polymer layer 232 may be substantially the same as a thickness of the third polymer layer 233. However, the thickness of the first polymer layer 231 may be less than the thickness of each of the second polymer layer 232 and the third polymer layer 233.

Openings for forming the backside bonding pads 139 may then be formed in the third polymer layer 233. The openings may extend through the third polymer layer 233 so as to expose a surface of the second RDL 132 through the openings. The openings may be formed, for example, by a photolithographic process including forming a patterned photoresist layer, and etching (e.g., wet etching, dry etching, etc.) the third polymer layer 233 through the patterned photoresist layer. The etching may be performed, for example, in one or more etching steps.

The backside bonding pads 139 and the TVs 145 may then be formed in one or more electroplating processes. In one or more embodiments, a seed layer (not shown) is first formed in the openings in the third polymer layer 233 and on the surface of the third polymer layer 233. The seed layer may be similar to the seed layer described above for forming the backside connector 150 and first RDL 131, and formed by a similar process. A metal material may then be electroplated on the seed layer to form the backside bonding pads 139 and the TVs 145. The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

FIG. 2C is a vertical cross-sectional view of an intermediate structure including the semiconductor die 120 on the backside RDL structure 130, according to one or more embodiments. The adhesive layer 129 may be applied to the surface of the semiconductor die 120 (i.e., the surface opposite the active region 122). The semiconductor die 120 may then be placed on a surface of the third polymer layer 233 of the backside RDL structure 130. In at least one embodiment, the semiconductor die 120 may then be placed on a surface of the third polymer layer 233 by a pick-and-place (PnP) process (e.g., a robotic PnP process). The semiconductor die 120 may then be pressed onto the surface of the third polymer layer 233, and the adhesive layer 129 cured so as to securely fix the semiconductor die 120 is to the surface.

As illustrated in FIG. 2C, the semiconductor die 120 may be attached to the third polymer layer 233 with the semiconductor die bonding pads 127 formed thereon in contact with the semiconductor die contact pads 123. A height of the semiconductor die bonding pads 127 in the z-direction may be less than a height of each of the TVs 145. Thus, for example, in the earlier step of forming of the TVs 145, the electroplating process may be continued at least until the height of each of the TVs 145 is ensured to be greater than the height of the semiconductor die bonding pads 127.

FIG. 2D is a vertical cross-sectional view of an intermediate structure including the encapsulant layer 140 on the backside RDL structure 130, according to one or more embodiments. The encapsulant layer 140 may be formed by a sequence of an over-molding process and a planarization process. In particular, the encapsulation layer 140 (e.g., an epoxy molding compound (EMC) may be formed over the backside RDL structure 130 to fill in the gaps between the semiconductor die 120 and the TVs 145 and encapsulate the semiconductor die 120 and the TVs 145. The encapsulation layer 140 may further cover the semiconductor die 120 and the TVs 145. The encapsulation layer 140 may be formed, for example, by a deposition process such as CVD, PECVD, PVD, spin coating, lamination or other suitable deposition technique.

FIG. 2E is a vertical cross-sectional view of an intermediate structure including the encapsulant layer 140 after performing the planarization process, according to one or more embodiments. As illustrated in FIG. 2E, the planarization process may be performed on a surface 140a of the encapsulation layer 140 until a surface 145a of the TVs and a surface of the semiconductor die bonding pads 127 are exposed. That is, the planarization process may be performed until the surface 140a of the encapsulation layer 140 is substantially coplanar with the surface 145a of the TVs 145 and the surface of the semiconductor die bonding pads 127. The planarization process may include, for example, a mechanical grinding process and/or a chemical mechanical polishing (CMP) process.

FIG. 2F is a vertical cross-sectional view of an intermediate structure including the frontside RDL structure 110, according to one or more embodiments. The polymer layers 114 and frontside RDL structure 110 may be formed by processes similar to the processes described above for forming the backside RDL structure 130. In particular, the proximal polymer layer 114p may be formed on the encapsulation layer 140. The proximal polymer layer 114p may be formed, for example, by a deposition process such as CVD, PECVD, PVD, spin coating, lamination or other suitable deposition technique. Openings may be formed in the proximal polymer layer 114p (e.g., by etching in a photolithographic process). A redistribution layer 113 may then be formed (e.g., by an electroplating process) in the openings and on the proximal polymer layer 114p. In this manner, the vias 118 (e.g., frontside bonding pads) may be formed so as to contact the semiconductor die bonding pads 127, and the vias 119 (e.g., frontside bonding pads) may be formed so as to contact the TVs 145. The remaining polymer layers 114 and redistribution layers 113 of the frontside RDL structure 110 may then be alternatingly formed in a similar manner.

Openings may then be formed (e.g., by a photolithographic process) in the distal polymer layer 114d and the UBM layer 115 may be formed (e.g., by an electroplating process) in the openings and on the surface of the distal polymer layer 114d. Solder balls 116 may then be formed on UBM layer 115. The solder balls 116 may be formed, for example, by a suitable process such as reflow, evaporation, ball drop, screen printing, or electroplating.

FIG. 2G is a vertical cross-sectional view of an intermediate structure on a frame mount 250, according to one or more embodiments. After the solder balls 116 are formed on the UBM layer 115, the intermediate structure may be inverted and mounted on the frame mount 250. In particular, the intermediate structure may be placed on the frame mount 250 so that the solder balls 116 contact a surface of the frame mount 250.

The intermediate structure may then be debonded from the carrier substrate 10. The intermediate structure may be debonded from the carrier substrate 10, for example, by decomposing (e.g., by using heat, ultraviolet (UV) light, etc.) the adhesive layer 210 that adhered the intermediate structure to the carrier substrate 10. A post-laser drill clean may then optionally be performed in order to clean a surface of the intermediate structure. A pre-solder layer (not shown) may also optionally be formed on the backside connector 150 (e.g., on the joint pad 156). The pre-solder layer may be formed, for example, by a suitable process such as reflow, evaporation, ball drop, screen printing, or electroplating.

An optional laser marking process may also performed on the intermediate structure. A singulation process may then be used to separate the package 100 from surrounding material (e.g., molding material). For example, a dicing saw may be used to separate the package 100 in the singulation process.

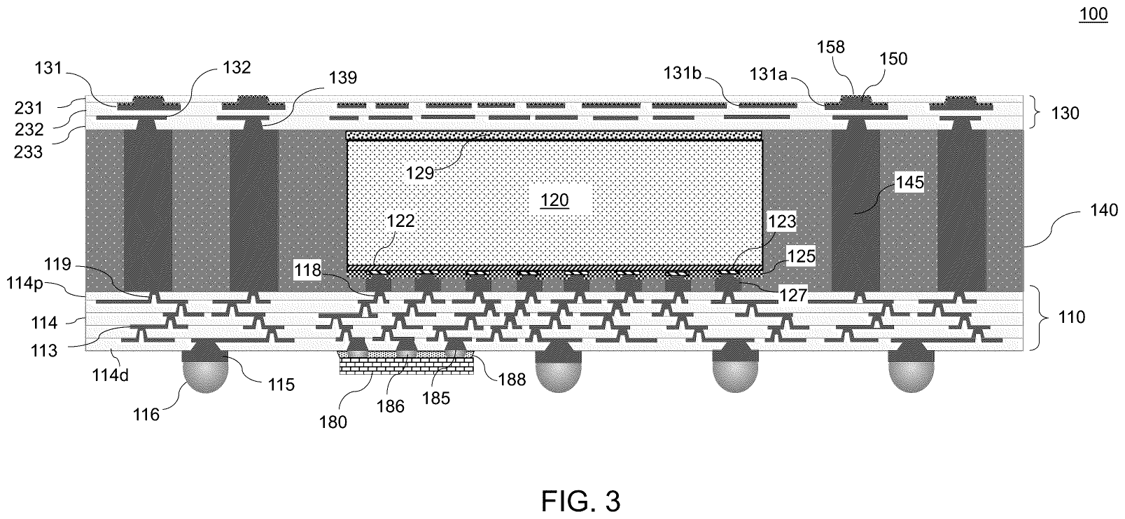

FIG. 3 is a vertical cross-sectional view of a first alternative configuration of the package 100, according to one or more embodiments. As illustrated in FIG. 3, the first alternative configuration is substantially the same as the basic configuration in FIG. 1A. However, the first alternative configuration may also include a barrier layer 158 on a surface of the backside connector 150. The barrier layer 158 may also be included on a backside connector portion 131a of the first RDL 131 (e.g., a portion of the first RDL 131 dedicating to connecting the backside RDL structure 130 to another structure or package). The barrier layer 158 may optionally be included on a routing portion 131b of the first RDL 131 (e.g., a portion of the first RDL 131 dedicating to routing in the backside RDL structure 130). The barrier layer 158 may include a barrier material such titanium. Other suitable barrier materials may be used. The barrier layer 158 may have a thickness that is less than a thickness of the first RDL 131. The barrier layer 158 may be formed, for example, prior to the formation of the first RDL 131 and backside connectors 150, and may serve as a protective foundation for the first RDL 131 and backside connectors 150.

The first alternative configuration may also include an integrated passive device (IPD) 180 on the distal polymer layer 114d (e.g., on a bottom surface of the frontside RDL structure 110). The IPD 180 may be formed in the place of a UBM layer 115 and solder ball 116 connected thereto. The IPD 180 may include a capacitor (e.g., a metal-insulator-metal (MIM) capacitor), a resistor, an inductor or the like, or a combination thereof. The number of the IPD 180 is not limited to that is shown in FIG. 3, but may be vary depending upon the application.

The IPD 180 may be electrically connected to the redistribution layer 113 in the distal polymer layer 114d of the frontside RDL structure 110. In particular, one or more UBM layers 185 may be formed in the distal polymer layer 114d and contact the redistribution layer 113. The UBM layer 185 may have a surface that is substantially coplanar with a surface of the distal polymer layer 114d (e.g., the bottom surface of the frontside RDL structure 110). One or more solder balls 186 may be formed on the UBM layers 185, respectively. The IPD 180 may be mounted on the distal polymer layer 114d so that one or more contacts of the IPD 180 contact the solder balls 186. The UBM layers 185 may include the same materials as the UBM layers 115, and may be formed concurrently with the forming of the UBM layers 115 (e.g., see FIG. 2F and associated text). The solder balls 186 may include the same materials as the solder balls 116 and may be formed concurrently with the forming of the solder balls 116. (e.g., see FIG. 2F and associated text).

An underfill layer 188 may be formed on an around the solder balls 116, and between the distal polymer layer 114d and the IPD 180. The underfill layer 188 may help to fix IPD 180 to the frontside RDL structure 110. The underfill layer 188 may have a low viscosity (e.g., less than about 5,000 cP at 10 rpm), and may be formed of an epoxy-based polymeric material. In at least one embodiment, the underfill layer 188 may include a capillary underfill including a mixture of epoxy and silica. In at least one embodiment, the underfill layer 188 may include a low-viscosity suspension of silica in prepolymer.

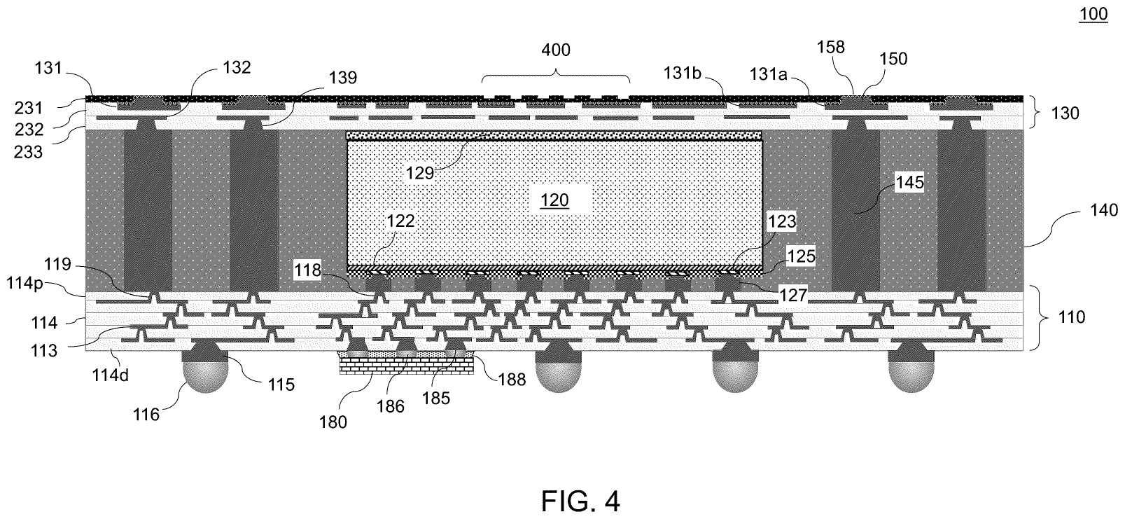

FIG. 4 is a vertical cross-sectional view of a second alternative configuration of the package 100, according to one or more embodiments. The second alternative configuration may be substantially similar to the first alternative configuration. However, in the second alternative configuration, the first polymer layer 231 may include a dark material to allow a laser marking 400 to be included on the package 100. The dark material of first polymer layer 131 may include, for example, a polymer material, a molding material, or other suitable dielectric materials. A dye (e.g., black dye) may be added to the dielectric material in order to provide a dark coloring to the first polymer layer 231. In at least one embodiment, the dielectric material may include, polyimide (PI), epoxy resin, acrylic resin, phenol resin, benzocyclobutene (BCB), polybenzoxazole (PBO), or any other suitable dielectric material.

The laser marking 400 may be formed on a surface of the first polymer layer 231 by using a laser. That is, the marking may include one or more cuts (e.g., recesses, voids, etc.) made by the laser in a surface of the first polymer layer 231. The laser may include, for example, a focused ion beam (FIB) laser, although other suitable lasers may be used. The first polymer layer 231 may be devoid of filler and may form a readable marking (e.g., a readable letter) by a void mode within the first polymer layer 231. A thickness of the first polymer layer 231 including the dark material may be at least 11.5 μm, although other suitable thicknesses may be used.

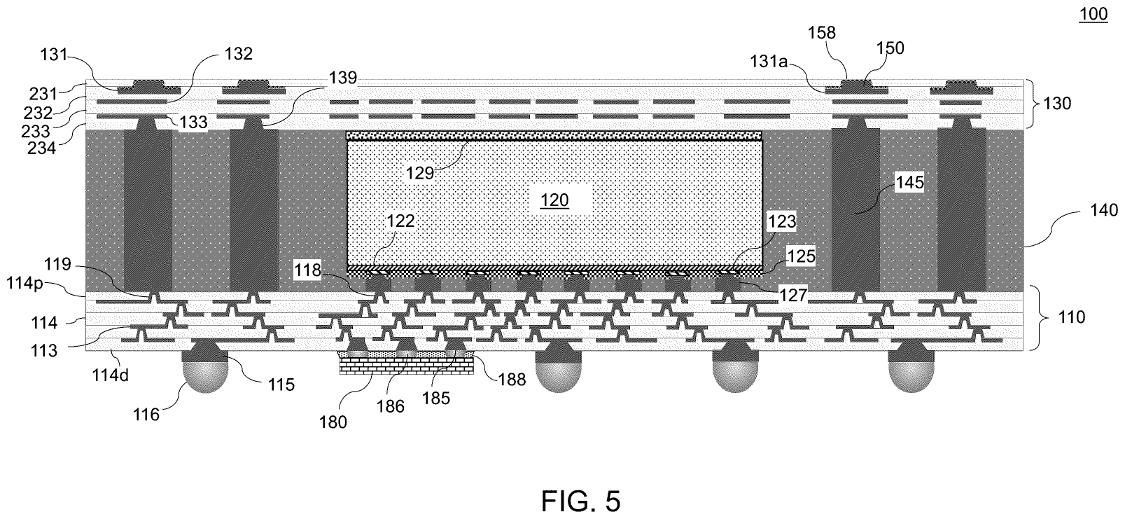

FIG. 5 is a vertical cross-sectional view of a third alternative configuration of the package 100, according to one or more embodiments. The third alternative configuration may be substantially similar to the first alternative configuration. However, in the third alternative configuration, the first RDL 131 in the backside RDL structure 130 may not include a routing layer. Note, for example, the absence of the routing portions 131b of the first RDL 131 in the first alternative configuration in FIG. 3. That is, first RDL 131 may have a function of providing a mechanism for contacting another structure (package) to the package 100, but the first RDL 130 may not include a routing function.

It should also be noted that the backside connector 150 (e.g., a UBM layer) may be formed with or without the routing portions 131b under different RDL layer counts combination. In particular, in contrast to the first alternative configuration, in the third alternative configuration, the backside RDL structure 130 may include four polymer layers—a first polymer layer 231, a second polymer layer 232, a third polymer layer 233 and a fourth polymer layer 234. The backside RDL structure 130 may also include three redistribution layers—a first RDL 131, a second RDL 132 and a third RDL 133. However, other numbers of polymer layers and redistribution layers maybe be included in the backside RDL structure 130.

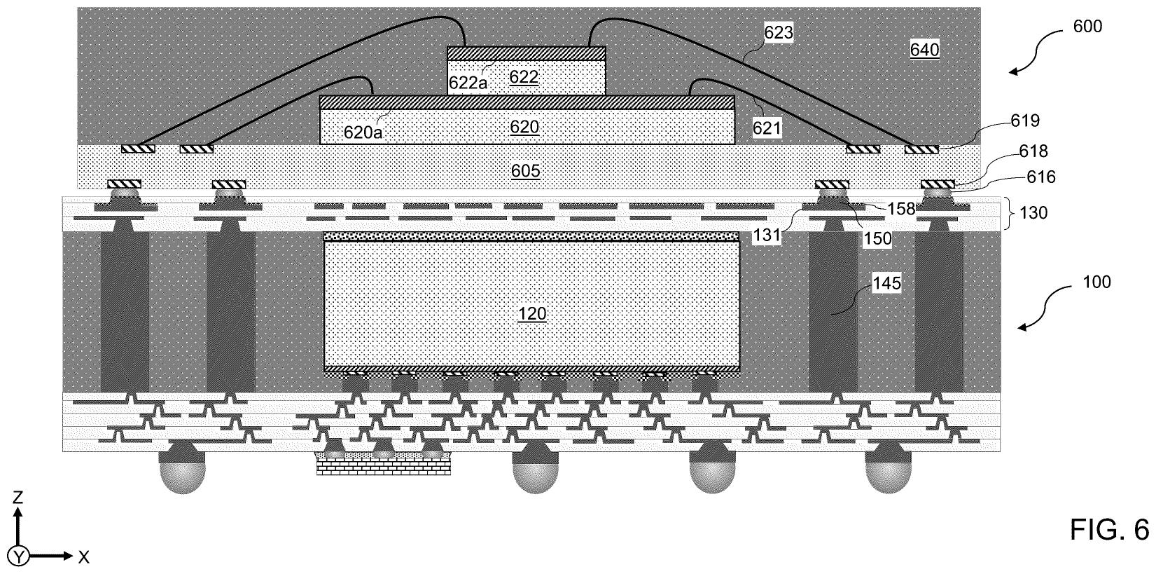

FIG. 6 is a vertical cross-sectional view of a fourth alternative configuration of the package 100, according to one or more embodiments. The fourth alternative configuration may be substantially similar to the first alternative configuration. However, in contrast to the first alternative configuration (e.g., a bottom only configuration) the fourth alternative configuration may have a package-on-package configuration (e.g., a package-on-package configuration). As illustrated in FIG. 6, an upper package 600 may be mounted on the backside RDL structure 130 through the backside connectors 150. In particular, one or more solder balls 616 may be disposed on the backside connectors 150 for electrically connecting the upper package 600 to the package 100.

The upper package 600 may include a package substrate 605 including bottom contact pads 618 on a bottom surface of the package substrate 605. The bottom contact pads 618 may contact the solder balls 616 on the backside connectors 150 in the package 100. The package substrate 605 may also include upper contact pads 619 on an upper surface of the package substrate 605. The upper contact pads 619 may be electrically connected to the bottom contact pads 618 through various wiring interconnect layers and vias in the package substrate 605.

The upper package 600 may also include a first upper semiconductor die 620 mounted on the package substrate 605. The first upper semiconductor die 620 may include an active region 620a connected to the upper contact pads 619 through one or more wires 621. The upper package 600 may also include a second upper semiconductor die 622 mounted on the first upper semiconductor die 620. The second upper semiconductor die 622 may have a width in the x-direction that is less than a width of the first semiconductor die 620. The second upper semiconductor die 622 may include an active region 622a connected to the upper contact pads 619 through one or more wires 623. Each of the first upper semiconductor die 620 and the second upper semiconductor die 622 may be similar to the semiconductor die 120 described above with respect to FIG. 1A.

The upper package 600 may also include an upper encapsulation layer 640 similar to the encapsulation layer 140 in the package 100. The upper encapsulation layer 640 may formed on the package substrate 605 and may substantially encapsulate the first upper semiconductor die 620, the second upper semiconductor die 622, the wires 621 and the wires 623.

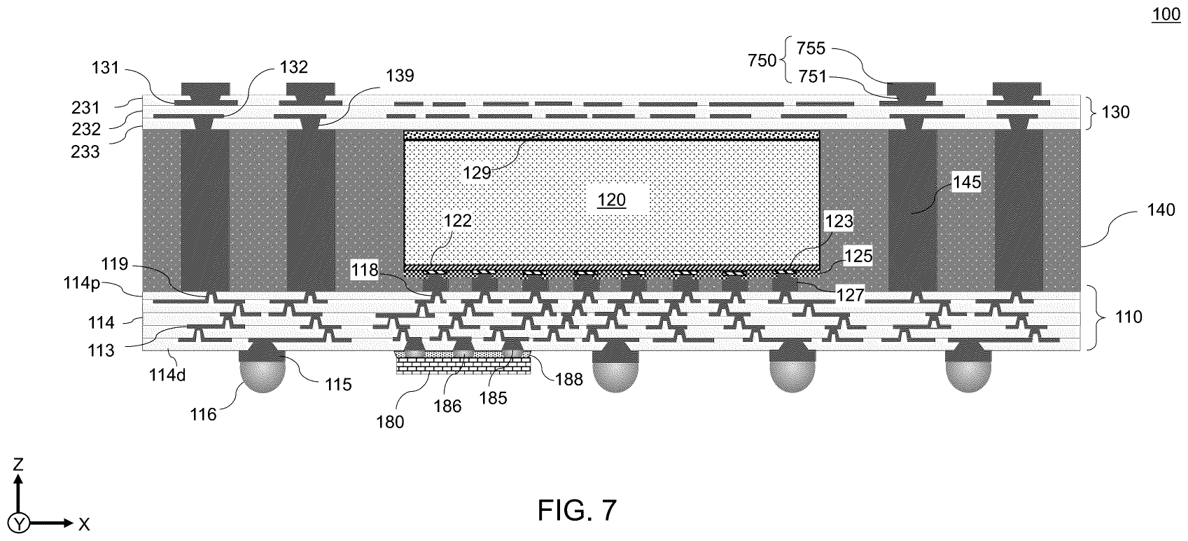

FIG. 7 is a vertical cross-sectional view of a fifth alternative configuration of the package 100, according to one or more embodiments. The fifth alternative configuration may be substantially similar to the first alternative configuration, except that there may be notable differences in the backside RDL structure 130.

In contrast to the first alternative configuration, in the fifth alternative configuration the backside RDL structure 130 may include a backside connector 750 (e.g., an exposed UBM layer). The backside connector 750 may include a tapered portion 751 extending from the upper surface of the first polymer layer 231 through the first polymer layer 231 and contacting the first RDL 131. The tapered portion 751 may have a circular cross-section in the x-y plane, although other suitable shapes may be used. The tapered portion 751 may have a tapered configuration, but in contrast to the tapered portion of the backside connector 150, the tapered portion 751 may be tapered so that a width (e.g., diameter) of the tapered portion 751 may increase in a direction away from the frontside RDL structure 110. That is, a distal end of the tapered portion 751 (e.g., a contact surface of the tapered portion 751) may have a width that is greater than a width of the proximal end of the tapered portion 751.

The backside connector 750 may also include a pillar structure 755 (e.g., copper pillar) outside of the first polymer layer 231 (e.g., exposed) and on the upper surface of the first polymer layer 231. The pillar structure 755 may contact a distal end of the tapered portion 751 (e.g., a contact surface of the tapered portion 751). The pillar structure 755 may have a circular cross-section in the x-y plane, although other suitable shapes may be used. The pillar structure 755 may have a thickness in the z-direction that is greater than 20 μm. The pillar structure 755 may have a width in the x-direction that is greater than the thickness of the pillar structure 755. In at least one embodiment, the radius of the pillar structure 755 may be about 10 μm greater than a largest radius of the tapered portion 751. In at least one embodiment, the width of the pillar structure 755 may be in a range from 80% to 120% of a width of the TVs 145. Further, in a plan view looking down onto the upper surface of the first polymer layer 231, a combined area of the all of the pillar structures 755 may be in a range from 1% to 20% of the total area of the upper surface of the first polymer layer 231.

The backside connector 750 may include the same materials as the first RDL 131. In particular, the backside connector 750 may have one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

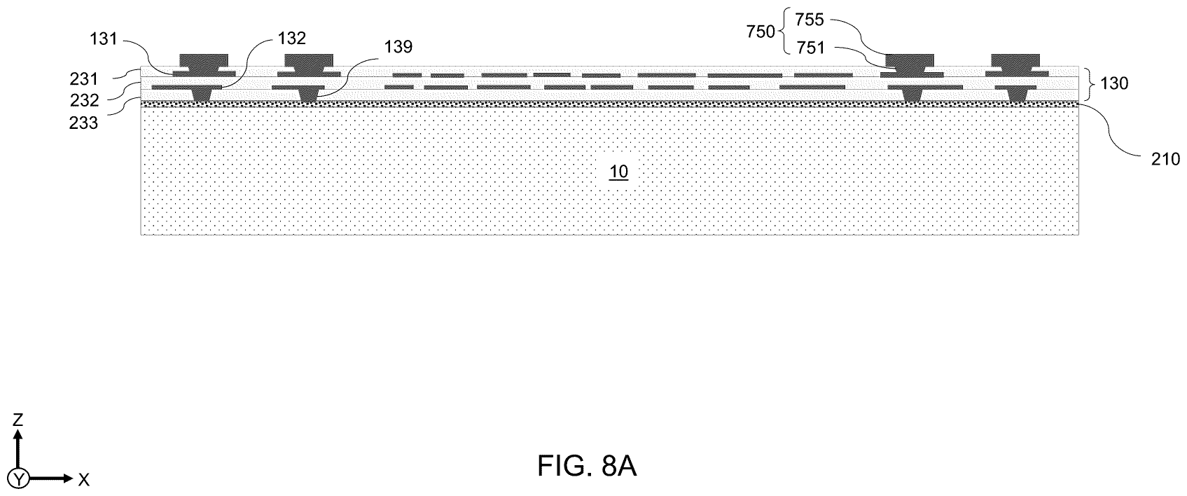

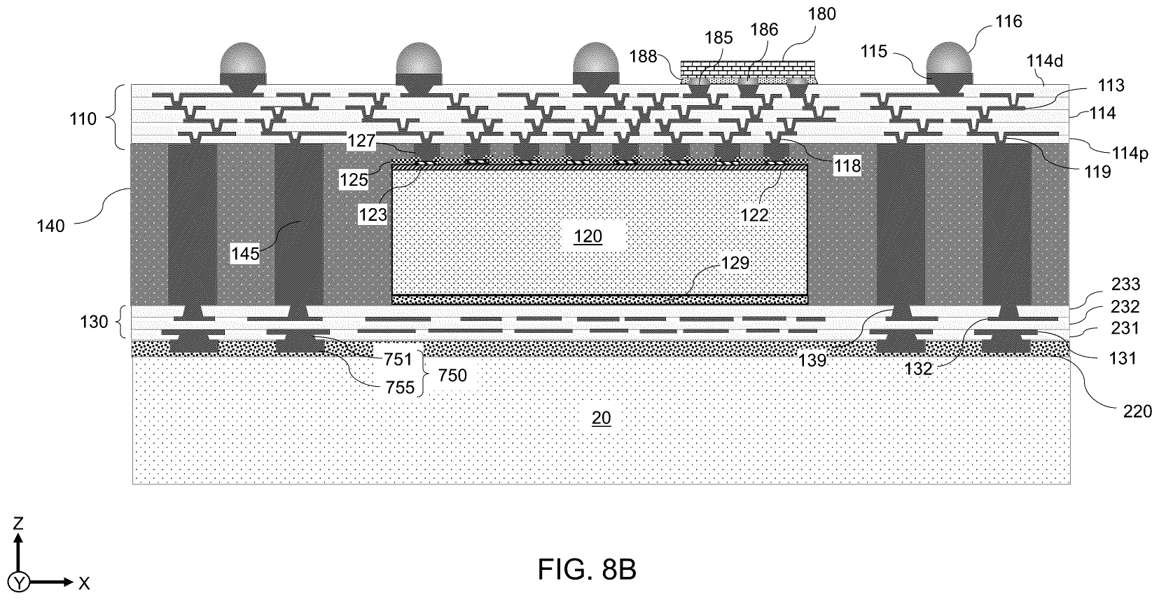

FIGS. 8A-8B are vertical cross-sectional views of various intermediate structures in a method of forming the fifth alternative configuration package 100 in FIG. 7, according to one or more embodiments. In particular, FIG. 8A is a vertical cross-sectional view of an intermediate structure including the backside RDL structure 130 bonded to the carrier substrate 10, according to one or more embodiments. In the fifth alternative configuration, the polymer layer and RDL layers of the backside RDL structure 130 may be formed in reverse order. That is, the third polymer layer 233 may be formed on the adhesive layer 210 on the carrier substrate 10, and the second RDL 132 may be formed on the third polymer layer 233. The second polymer layer 232 may then be formed on the third polymer layer 233 including the second RDL 132, and the first RDL 131 may then be formed on the second polymer layer 232. The first polymer layer 231 may then be formed on the second polymer layer 232 including the first RDL 131. Openings may then be formed in the first polymer layer 131 (e.g., by a photolithographic process as described above with respect to FIG. 2A). The tapered portions 751 and the pillar structures 755 of the backside connector 750 may then be formed (e.g., in an electroplating process as described above with respect to FIG. 2A) in the openings (respectively) and on the upper surface of the first polymer layer 231.

FIG. 8B is a vertical cross-sectional view of an intermediate structure including the semiconductor die 120 and frontside RDL structure 110, according to one or more embodiments. After the formation of the backside connector 750, the intermediate structure including the backside RDL structure 130 may be inverted and the upper surface of the first polymer layer 231 bonded to a second carrier substrate 20 through an adhesive 220 (similar to adhesive 210). The carrier substrate 10 may then be debonded from the backside RDL structure 130. The forming of the package 100 may then proceed similar to the manner described above with respect to FIGS. 2B-2G. The IPD 180 may be formed on the frontside RDL structure 110 as described above with respect to FIG. 3.

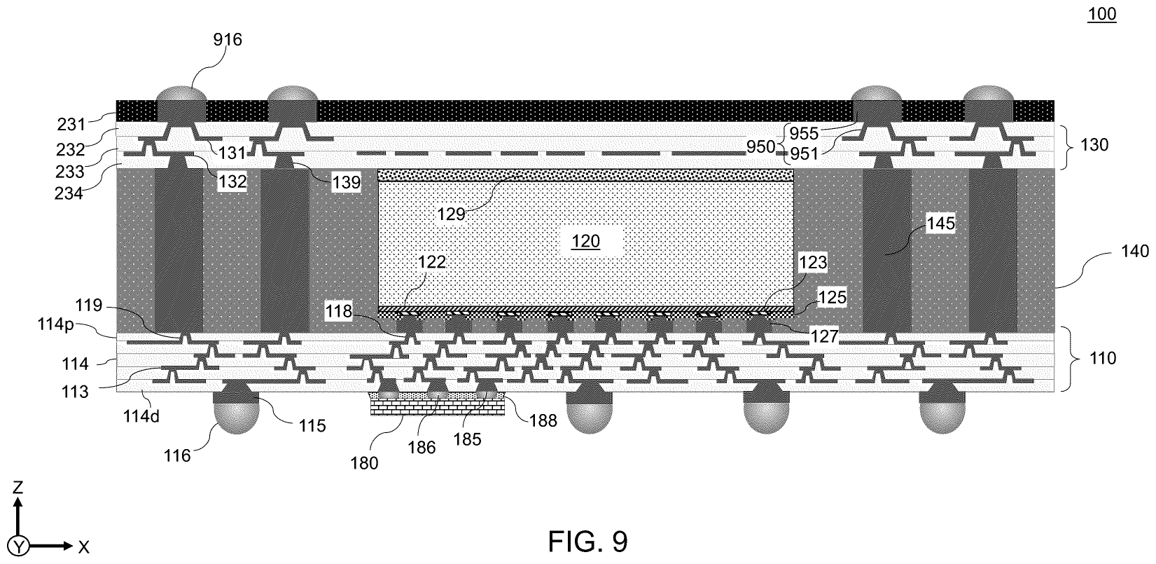

FIG. 9 is a vertical cross-sectional view of a sixth alternative configuration of the package 100, according to one or more embodiments. The sixth alternative configuration may be substantially similar to the first alternative configuration. It should be noted that the barrier layer 158 is omitted from FIG. 9 for ease of explanation.

The first polymer layer 231 in the sixth alternative configuration may or may not include a dark material (e.g., dye) to allow a laser marking to be included on the package 100. The first polymer layer 131 may include, for example, a polymer material, a molding material, or other suitable dielectric materials. The dark material (e.g., black dye) may be added to the dielectric material in order to provide a dark coloring to the first polymer layer 231. In at least one embodiment, the dielectric material may include, polyimide (PI), epoxy resin, acrylic resin, phenol resin, benzocyclobutene (BCB), polybenzoxazole (PBO), or any other suitable dielectric material.

The laser marking (not shown) may be formed on a surface of the first polymer layer 231 by using a laser. That is, the marking may include one or more cuts (e.g., recesses, voids, etc.) made by the laser in a surface of the first polymer layer 231. The laser may include, for example, a focused ion beam (FIB) laser, although other suitable lasers may be used. The first polymer layer 231 may be devoid of filler and may form a readable marking (e.g., a readable letter) by a void mode within the first polymer layer 231. A thickness of the first polymer layer 231 including the dark material may be at least 11.5 μm, although other suitable thicknesses may be used.

The backside RDL structure 130 may further the second polymer layer 232 on the firsts polymer layer 231 and the first RDL 131 on the second polymer layer 232, and the third polymer layer 233 on the second polymer layer 232 and the second RDL 132 on the third polymer layer 233. The backside RDL structure 130 may also include a fourth polymer layer 234 and the backside bonding pads 139 may be formed in the fourth polymer layer 234 and contact the TVs 145.

The sixth alternative configuration may also include a backside connector 950 which may include a pillar structure 955 in the first polymer layer 231 and a tapered portion 951 in the second polymer layer 232. The tapered portion 951 may extend from the first RDL 131 on the second polymer layer 232 through the second polymer layer 232 and contact the pillar structure 955. In particular, the pillar structure 955 may contact a distal end of the tapered portion 951 (e.g., a contact surface of the tapered portion 951). The tapered portion 951 may have a circular cross-section in the x-y plane, although other suitable shapes may be used. The tapered portion 951 may have a tapered configuration such that a width (e.g., diameter) of the tapered portion 951 may decrease in a direction away from the frontside RDL structure 110. That is, the distal end of the tapered portion 951 (e.g., contact surface of the tapered portion 951) may have a width that is less than a width of the proximal end of the tapered portion 951.

The pillar structure 955 may be substantially encapsulated by the first polymer layer 231 in the x-y direction. The pillar structure 955 may have a circular cross-section in the x-y plane, although other suitable shapes may be used. The pillar structure 955 may have a thickness in the z-direction that is greater than 20 μm. In at least one embodiment, the pillar structure 955 may have a thickness that is substantially the same as a thickness of the first polymer layer 231. In at least one embodiment, a distal surface of the first polymer layer 231 may be substantially coplanar with a distal surface of the pillar structure 955, so that the distal surface of the pillar structure 955 may be exposed.

The pillar structure 955 may also have a width in the x-direction that is greater than the thickness of the pillar structure 955. The width of the pillar structure 955 may also be greater than a width of the tapered portion 951 at the distal end of the tapered portion 951 (e.g., contact surface of the tapered portion 951). In at least one embodiment, the radius of the pillar structure 955 may be about 10 μm greater than a radius of the tapered portion 951 at the distal end of the tapered portion 951. In at least one embodiment, the width of the pillar structure 955 may be in a range from 80% to 120% of a width of the TVs 145. Further, in a plan view looking down onto the upper surface of the first polymer layer 231, a combined area of the all of the pillar structures 955 may be in a range from 1% to 20% of the total area of the upper surface of the first polymer layer 231. A pre-solder layer 916 (e.g., solder ball similar to the solder ball 116) may also be formed on the distal surface of the pillar structure 955. The pre-solder layer 916 may include a convex shape, or another suitable shape. The pre-solder layer 916 may be formed, for example, by a suitable process such as reflow, evaporation, ball drop, screen printing, or electroplating.

The backside connector 950 may include the same materials as the first RDL 131. In particular, the backside connector 950 may have one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

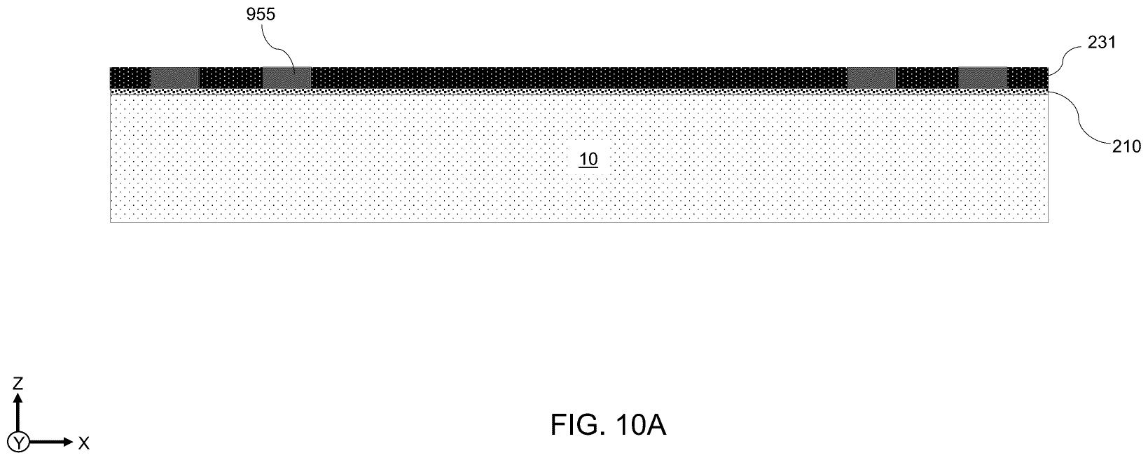

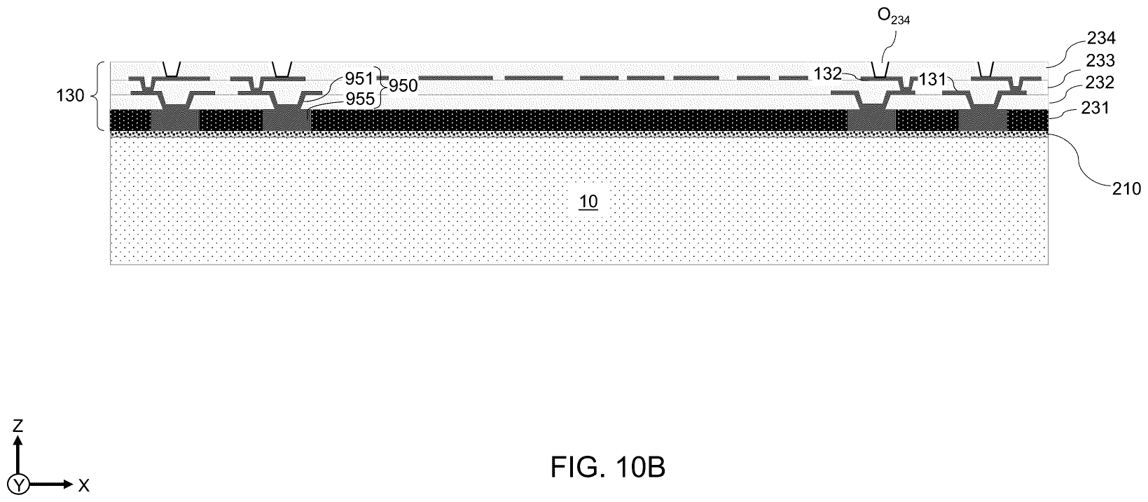

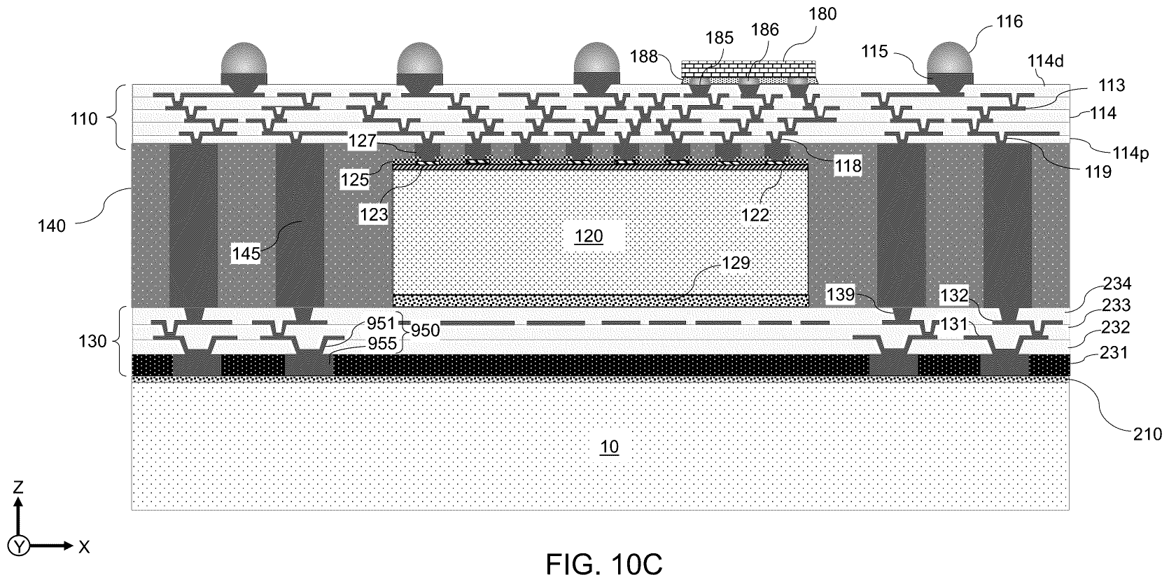

FIGS. 10A-10C are vertical cross-sectional views of various intermediate structures in a method of forming the sixth alternative configuration package 100 in FIG. 9, according to one or more embodiments. In particular, FIG. 10A is a vertical cross-sectional view of an intermediate structure including the first polymer layer 231 including dark material bonded to the carrier substrate 10, according to one or more embodiments. In the sixth alternative configuration, the first polymer layer 231 including the dark material may be formed (e.g., by a suitable deposition process) on the adhesive layer 210 on the carrier substrate 10. Openings for forming the pillar structures 955 may then be formed (e.g., by etching in a photolithographic process) in the first polymer layer 231. The pillar structures 955 of the backside connector 950 may then be formed (e.g., in an electroplating process as described above with respect to FIG. 2A) in the openings (respectively) and on the upper surface of the first polymer layer 231. A grinding process (e.g., micro-grinding, polishing by CMP, etc.) may then be performed to smooth the surface of the first polymer layer 231.

FIG. 10B is a vertical cross-sectional view of an intermediate structure including the backside RDL structure 130 bonded to the carrier substrate 10, according to one or more embodiments. As illustrated in FIG. 10B, the second polymer layer 232 may be formed (e.g., by a suitable deposition process) on the first polymer layer 131 and over the pillar structures 955. Openings for forming the tapered portion 951 may then be formed (e.g., by etching in a photolithographic process) in the second polymer layer 232. The first RDL 131 may then be formed (e.g., in an electroplating process as described above with respect to FIG. 2A) on the second polymer layer 232, and the tapered portion 951 of the backside connector 950 may be formed concurrently with the forming of the first RDL 131. A thickness of the first RDL 131 may be less than a typical thickness of a redistribution layer. In at least one embodiment, the thickness of the first RDL 131 may be in a range from 3.0 μm to 6.0 μm (e.g., about 4.5 μm).

The third polymer layer 233 may then be formed on the second polymer layer 232, the second RDL 132 may be formed on the third polymer layer 233, and the fourth polymer layer 234 may be formed on the third polymer layer 233. Openings O234 may then be formed in the fourth polymer layer 131 (e.g., by a photolithographic process as described above with respect to FIG. 2A) for the subsequent formation of the backside bonding pads 139.

FIG. 10C is a vertical cross-sectional view of an intermediate structure including the semiconductor die 120 and frontside RDL structure 110, according to one or more embodiments. After the formation of the openings O234 in the fourth polymer layer 131, the backside bonding pads 139 may be formed in the openings O234 concurrently with the forming of the TVs 145 (e.g., in an electroplating process as described above with respect to FIG. 2B). The semiconductor die 120 may then be attached to the backside RDL structure 130, and the encapsulation layer 140 and frontside RDL structure 110 may then be formed in succession as described above with respect to FIGS. 2C-2F. The forming of the package 100 may then proceed to completion similar to the manner described above with respect to FIG. 2G. The pre-solder layer 916 (e.g., solder ball similar to the solder ball 116) may optionally be formed on the distal surface of the pillar structure 955, and the IPD 180 may optionally be formed on the frontside RDL structure 110 as described above with respect to FIG. 3.

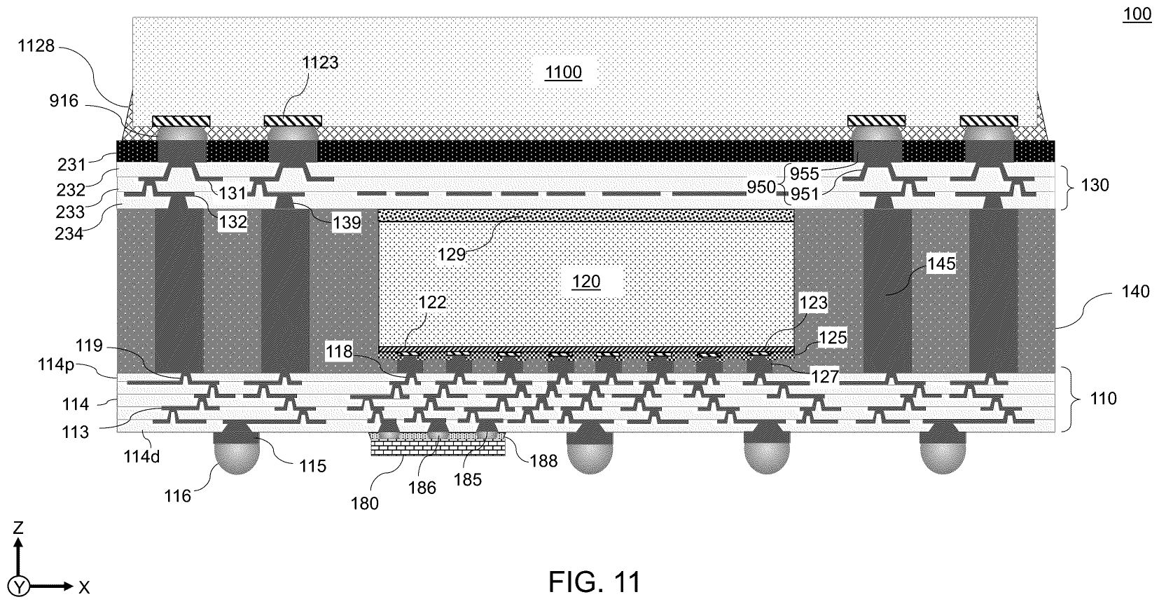

FIG. 11 is a vertical cross-sectional view of a seventh alternative configuration of the package 100, according to one or more embodiments. The seventh alternative configuration may be substantially similar to the sixth alternative configuration in FIG. 9. The seventh alternative configuration may also be formed by a method substantially similar to the method used to form the sixth alternative configuration (e.g., see FIGS. 10A-10C).

However, in contrast to the sixth alternative configuration (e.g., a bottom only configuration) the seventh alternative configuration may have a package-on-package configuration. As illustrated in FIG. 11, an upper package 1100 may be mounted on the backside RDL structure 130 through the backside connectors 950. In particular, the upper package 600 may be electrically connected to the package 100 by the pre-solder layer 916 (e.g., solder balls).

The upper package 1100 may be similar to the semiconductor die 120 described above with respect to FIG. 1A. In at least one embodiment, the upper package 1100 may include a memory device such as a DRAM device. In at least one embodiment, the upper package 1100 is a DRAM device and the pre-solder layer 916 may form a DRAM joint connecting the DRAM device to the package 100. The upper package 1100 may include bottom contact pads 1123 on a bottom surface of the upper package 1100. The bottom contact pads 1123 may contact the solder balls 916 on the backside connectors 950 in the package 100. The bottom contact pads 1123 may be electrically connected to an active region of the upper package 1100. An underfill layer 1128 (similar to underfill layer 188) may be formed between the upper package 1100 and the backside RDL structure 130, and help to fix the upper package 1100 to the package 100.

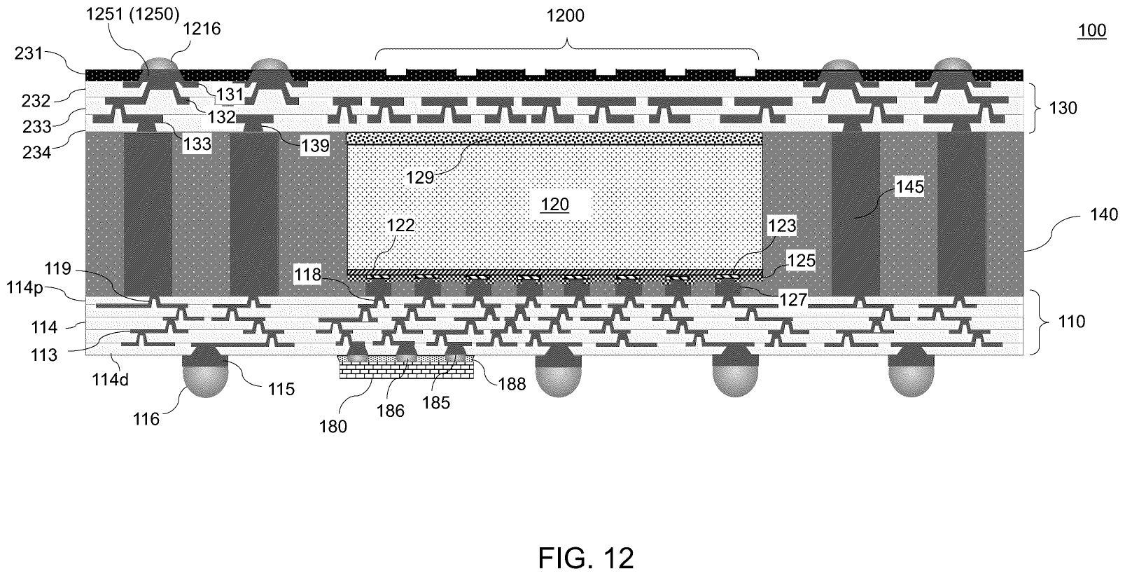

FIG. 12 is a vertical cross-sectional view of an eighth alternative configuration of the package 100, according to one or more embodiments. The eighth alternative configuration may be substantially similar to the sixth alternative configuration in FIG. 9. The eighth alternative configuration may also be formed by a method substantially similar to the method used to form the sixth alternative configuration (e.g., see FIGS. 10A-10C).

The eighth alternative configuration may include the backside RDL structure 130 including the first polymer layer 231. The first polymer layer 231 may or may not include the dark material (e.g., dye) for allowing the first polymer layer 231 to include the laser marking 1200 (similar to laser marking 400 in FIG. 4). The first RDL 131 may be formed on a surface of the first polymer layer 231.

A backside connector 1250 may project from the first RDL 131 into the first polymer layer 231. The backside connector 1250 may extend from a distal side of the first RDL 131 and include a tapered portion 1251 (e.g., via portion) having a width that decreases in a direction away from the first RDL 131. The tapered portion 1251 (e.g., via portion) having distal end that may be substantially coplanar with a distal surface of the first polymer layer 231. The distal end of the tapered portion 1251 may serve as a joint pad. A pre-solder layer 1216 (e.g., similar to pre-solder layer 916) may be located on the distal end of the tapered portion. The pre-solder layer 1216 may include a convex shape, or another suitable shape. The pre-solder layer 1216 may be formed, for example, by a suitable process such as reflow, evaporation, ball drop, screen printing, or electroplating.

The second RDL 132 may be formed on a surface of the second polymer layer 232 and include a via portion extending through the second polymer layer 232 to contact the backside connector 1250. The third RDL 133 may be formed on a surface of the third polymer layer 233 and include a via portion extending through the third polymer layer 233 to contact the second RDL 132. In at least one embodiment, the second RDL 132 and third RDL 133 may have a design routing function, but the first RDL 131 may not have a routing function but instead serve only for jointing (e.g., DRAM jointing).

It should be noted that the frontside RDL structure 110 in the eighth alternative configuration (as well as in the basic configuration of FIG. 1A or any of the other alternative configurations) may be replace with the backside RDL structure 130. This may be accomplished, for example, by constructing a first backside RDL structure 130 and second backside RDL structure, attaching the semiconductor die 120 on the first backside RDL structure 130, growing the TVs 145 on the first backside RDL structure 130 and forming the encapsulation layer 140 around the semiconductor die 120 and TVs 145 to form an intermediate structure. Then attaching the second backside RDL structure 130 to the intermediate structure. In this case, the package 100 may include the backside connectors 1250 (e.g., UBM structure) on dual sides. The backside connectors 1250 in the first backside RDL structure 130 may be used for, for example, for a PCB joint. The backside connectors 1250 in the second backside RDL structure 130 may be used for, for example, for a DRAM joint. It should also be noted that the backside RDL structure 130 may include a combination of backside connectors 150 (see FIG. 1A), backside connectors 750 (se FIG. 7), backside connectors 950 (see FIG. 9), and/or backside connectors 1250.

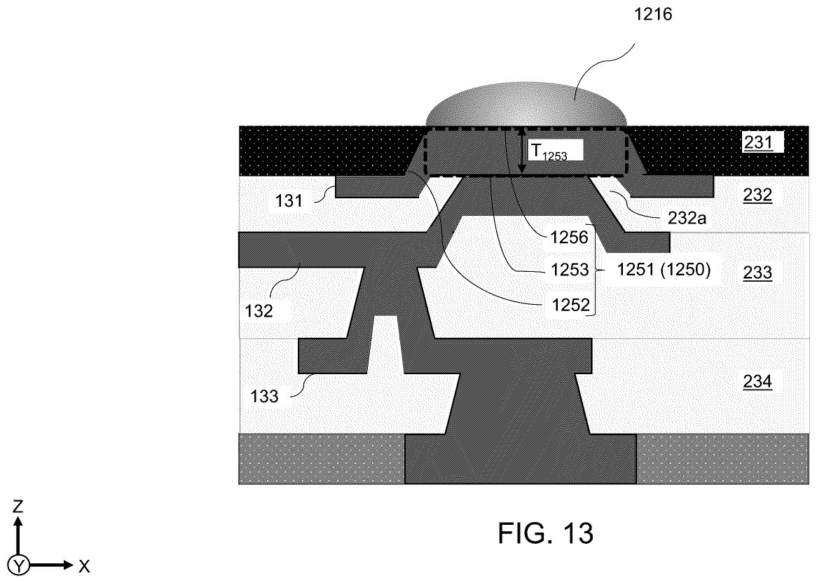

FIG. 13 is a vertical cross-sectional view of the backside connector 1250, according to one or more embodiments. As illustrated in FIG. 13, the backside connector 1250 may include a tapered portion 1251 projecting from the first RDL 131. The tapered portion 1251 may include a connector plate 1253 and a contact surface 1256 at an end of the tapered portion 1251. The contact surface 1256 may include a distal surface of the connector plate 1253 and/or a distal surface of the tapered portion 1251.

The tapered portion 1251 may also include a tapered sidewall 1252 on the connector plate 1253. The tapered sidewall 1252 may connect the connector plate 1253 to the first RDL 131. The tapered sidewall 1252 may be connected to a central portion of the first RDL 131. In particular, the first RDL 131 may include, for example, a “wing” portion extending from the tapered sidewall 1252 in the x-y plane around an entire periphery of the tapered sidewall 1252. In at least one embodiment, a length of the first RDL 131 extending from the tapered sidewall 1252 may be substantially uniform around the entire periphery of the tapered sidewall 1252.

The connector plate 1253 may have a thickness T1253 that is substantially the same as a thickness of the first polymer layer 231. In at least one embodiment, the thickness T1253 may be greater than a thickness of the first RDL 131 (e.g., in a range from 3 μm to 6 μm). In at least one embodiment, the thickness T1253 may be in a range from 4 μm to 20 μm. In at least one embodiment, the thickness T1253 may be greater than 20 μm. The contact surface 1256 (e.g., a distal surface of the connector plate 1253) may be substantially coplanar with the distal surface of the first polymer layer 231. That is, the contact surface 1256 may be exposed at the distal surface of the first polymer layer 231. The pre-solder layer 1216 may be disposed on the contact surface 1256.

The second RDL 132 may include a via portion that extends through the second polymer layer 232 and contacts a proximal surface of the connector plate 1253 of the tapered portion 1251. A thickness of the second polymer layer 232 may be in a range from 5 μm to 10 μm. A centerline of the via portion of the second RDL 132 may be substantially aligned in the z-direction with a centerline of the connector plate 1253 of the tapered portion 1251. The distal end of the via portion of the second RDL 132 may have a width in the x-direction that is less than a width of the proximal end of the connector plate 1253. As a result, the second polymer layer 232 may include a separating portion 232a that separates the tapered sidewall 1252 of the tapered portion 1251 from the via portion of the second RDL 132.

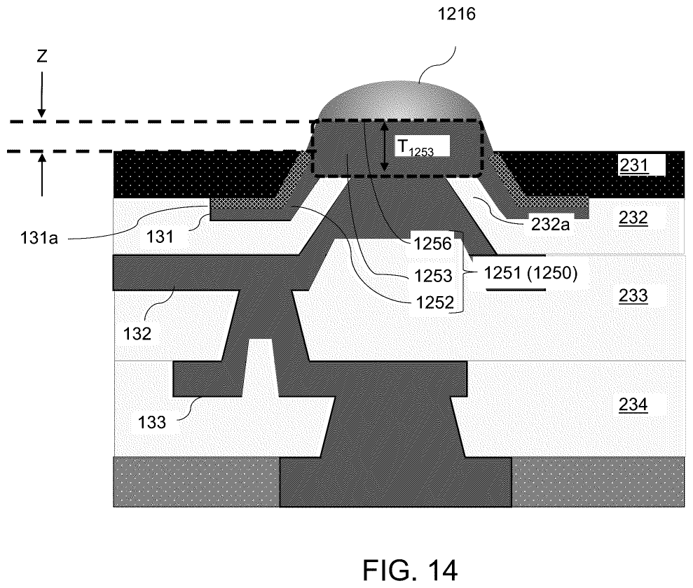

FIG. 14 is a vertical cross-sectional view of an alternative configuration of the backside connector 1250, according to one or more embodiments. In the alternative configuration, the backside connector 1250 may include a barrier layer 131a on the first RDL 131 and on at least a portion of the tapered sidewall 1252. The barrier layer 131a may be similar to the barrier layer 158 in FIG. 3. The barrier layer 131a may be formed, for example, at an interface between the first RDL 131 and the first polymer layer 231. The barrier layer 131a may also be formed, for example, at an interface between the first RDL 131 and the tapered sidewall 1252. The barrier layer 131a may have a distal end formed at the distal surface of the first polymer layer 231. The connector plate 1253 may include an exposed portion that extends beyond the distal surface of the first polymer layer 231. That is, the contact surface 1256 of the tapered portion 1251 may have a height that is greater than a height of the distal surface of the first polymer layer 231. A thickness Z of the exposed portion may be, for example, greater than 0.1 μm.

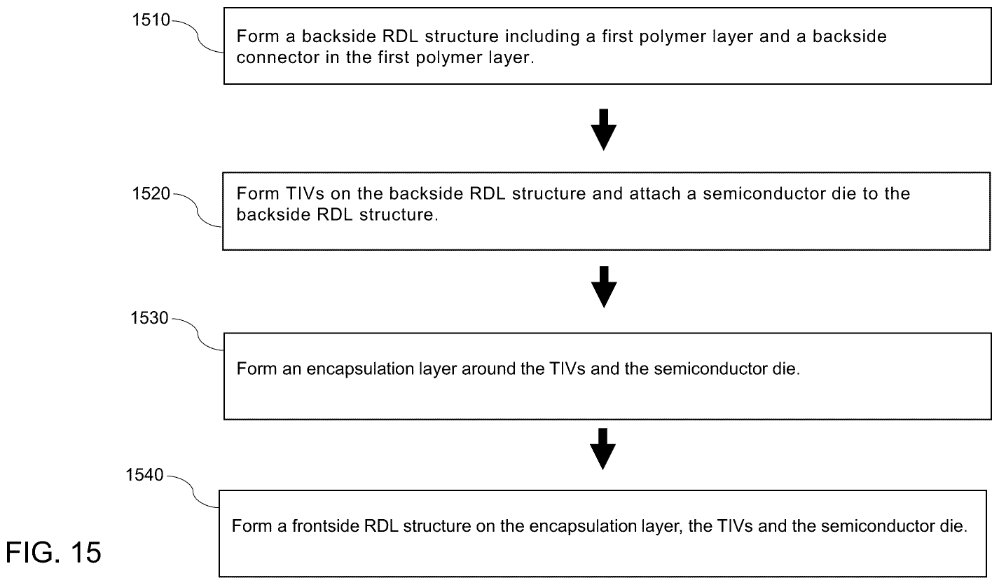

FIG. 15 is a flow chart illustrating a method of forming a package 100, according to one or more embodiments. The method includes Step 1510 of forming a backside RDL structure including a first polymer layer and a backside connector in the first polymer layer, Step 1520 of forming TVs on the backside RDL structure and attaching a semiconductor die to the backside RDL structure, Step 1530 of forming an encapsulation layer around the TVs and the semiconductor die, and Step 1540 of forming a frontside RDL structure on the encapsulation layer, the TVs and the semiconductor die.

Referring to FIGS. 1A-15, a package 100 may include a frontside redistribution layer (RDL) structure 110, a semiconductor die 120 on the frontside RDL structure 110, and a backside RDL structure 130 on the semiconductor die 120, including a first RDL 131, and a backside connector 150, 750, 950, 1250 extending from a distal side of the first RDL 131 and including a tapered portion 151, 751, 951, 1251 having a width that decreases in a direction away from the first RDL 131, wherein the tapered portion 151, 751, 951, 1251 may include a contact surface 156, 1256 at an end of the tapered portion 151, 751, 951, 1251. The tapered portion 151, 751, 951, 1251 may further include a connector plate 153, 1253 and tapered sidewalls 152, 1252 on the connector plate 153, 1253, and a thickness of the connector plate 153, 1253 may be greater than a thickness of the first RDL 131. The package 100 may further include an upper package 600 connected to the backside RDL structure 130 by the backside connector 150, 750, 950, 1250, and electrically connected to the semiconductor die 120. The upper package 600 may include a memory device. The package 100 may further include a through via (TV) 145 electrically connecting the frontside RDL structure 110 to the backside RDL structure 130, and an encapsulation layer 140 on the frontside RDL structure 110 and around the semiconductor die 120 and the TV 145, wherein the backside RDL structure 130 may be on the encapsulation layer 140. The frontside RDL structure 110 may include a first frontside RDL 113, and a frontside connector 115 extending from a distal side of the first frontside RDL 113 and including a tapered portion 151, 751, 951, 1251 having a width that increases in a direction away from the first frontside RDL 113. The backside RDL structure 130 may further include a first polymer layer 231 on a distal side of the backside RDL structure 130, wherein the first RDL 131 may be on the first polymer layer 231, a second polymer layer 232 on the first polymer layer 231 and the first RDL 131, and a second RDL 132 including a via extending through the second polymer layer 232 and contacting a proximal side of the connector plate 153, 1253. The backside RDL structure 130 may further include a first polymer layer 231, the tapered portion 151, 751, 951, 1251 extends through the first polymer layer 231 and the contact surface 156, 1256 may be substantially coplanar with a surface of the first polymer layer 231. The first polymer layer 231 may include a dark material and the surface of the first polymer layer 231 may include a laser marking for the package 100. The contact surface 156, 1256 may include a joint pad, and the backside RDL structure 130 further may include a solder layer on the joint pad. The backside connector 150, 750, 950, 1250 may further include a pillar structure 755, 955 connected to the contact surface 156, 1256. The backside RDL structure 130 may further include a first polymer layer 231 and the pillar structure 755, 955 may extend from contact surface 156, 1256 into the first polymer layer 231. A thickness of the pillar structure 755, 955 may be substantially the same as a thickness of the first polymer layer 231 so that a surface of the pillar structure 755, 955 may be substantially coplanar with a surface of the first polymer layer 231. The backside RDL structure 130 may further include a second polymer layer 232 on the first polymer layer 231 and the first RDL 131 may be on the second polymer layer 232, and the tapered portion 151, 751, 951, 1251 may extend through the second polymer layer 232 and the contact surface 156, 1256 may contact the pillar structure 755, 955 at an interface between the first polymer layer 231 and the second polymer layer 232. The pillar structure 755, 955 may have a width that may be greater than a width of the contact surface 156, 1256 and has a thickness greater than 20 μm.

Referring to FIGS. 1A-15, a method of forming a package 100, may include forming a backside redistribution layer (RDL) structure 130 including a first RDL 131, and a backside connector 150, 750, 950, 1250 extending from a distal side of the first RDL 131 and including a tapered portion 151, 751, 951, 1251 having a width that decreases in a direction away from the first RDL 131, wherein the tapered portion 151, 751, 951, 1251 may include a contact surface 156, 1256 at an end of the tapered portion 151, 751, 951, 1251, attaching a semiconductor die 120 to the backside RDL structure 130, forming an encapsulation layer 140 around the semiconductor die 120 on the backside RDL structure 130, and forming a frontside RDL structure 110 on the semiconductor die 120 and the encapsulation layer 140. The forming of the backside RDL structure 130 may include forming the tapered portion 151, 751, 951, 1251 to further include a connector plate 153, 1253 and tapered sidewalls 152, 1252 on the connector plate 153, 1253, such that a thickness of the connector plate 153, 1253 may be greater than a thickness of the first RDL 131. The forming of the backside RDL structure 130 may further include forming a first polymer layer 231 on a distal side of the backside RDL structure 130, wherein the first RDL 131 may be on the first polymer layer 231, forming a second polymer layer 232 on the first polymer layer 231 and the first RDL 131, and forming a second RDL 132 including a via extending through the second polymer layer 232 and contacting a proximal side of the connector plate 153, 1253. The forming of the backside RDL structure 130 may include forming the backside connector 150, 750, 950, 1250 to include a pillar structure 755, 955 connected to the contact surface 156, 1256.

Referring to FIGS. 7-8B, a package 100 may include a frontside redistribution layer (RDL) structure 110, a semiconductor die 120 on the frontside RDL structure 110, a backside RDL structure 130 on the semiconductor die 120, including a first RDL 131, and a first polymer layer 231 on the first RDL 131, and a backside connector 150, 750, 950, 1250 extending from a distal side of the first RDL 131 and including a pillar structure 755, 955 on the surface of the first polymer layer 231.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
a frontside redistribution layer (RDL) structure;
a semiconductor die on the frontside RDL structure; and
a backside RDL structure on the semiconductor die, comprising:
a first RDL; and
a backside connector extending from a distal side of the first RDL and including a tapered portion having a width that decreases in a direction away from the first RDL, wherein the tapered portion comprises a contact surface at an end of the tapered portion.

2. The package of claim 1, wherein the tapered portion further comprises a connector plate and tapered sidewalls on the connector plate, and a thickness of the connector plate is greater than a thickness of the first RDL.

3. The package of claim 1, further comprising:
an upper package connected to the backside RDL structure by the backside connector, and electrically connected to the semiconductor die.

4. The package of claim 3, wherein the upper package comprises a memory device.

5. The package of claim 1, further comprising:
a through via electrically connecting the frontside RDL structure to the backside RDL structure; and
an encapsulation layer on the frontside RDL structure and around the semiconductor die and the through via, wherein the backside RDL structure is on the encapsulation layer.

6. The package of claim 1, wherein the frontside RDL structure comprises:
a first frontside RDL; and
a frontside connector extending from a distal side of the first frontside RDL and including a tapered portion having a width that increases in a direction away from the first frontside RDL.

7. The package of claim 2, wherein the backside RDL structure further comprises:
a first polymer layer on a distal side of the backside RDL structure, wherein the first RDL is on the first polymer layer;
a second polymer layer on the first polymer layer and the first RDL; and
a second RDL including a via extending through the second polymer layer and contacting a proximal side of the connector plate.

8. The package of claim 1, wherein the backside RDL structure further comprises a first polymer layer, the tapered portion extends through the first polymer layer and the contact surface is substantially coplanar with a surface of the first polymer layer.

9. The package of claim 8, wherein the first polymer layer comprises a dark material and the surface of the first polymer layer comprises a laser marking for the package.

10. The package of claim 1, wherein the contact surface comprises a joint pad, and the backside RDL structure further comprises a solder layer on the joint pad.

11. The package of claim 1, wherein the backside connector further comprises a pillar structure connected to the contact surface.

12. The package of claim 11, wherein the backside RDL structure further comprises a first polymer layer and the pillar structure extends from contact surface into the first polymer layer.

13. The package of claim 7, wherein a thickness of the pillar structure is substantially the same as a thickness of the first polymer layer so that a surface of the pillar structure is substantially coplanar with a surface of the first polymer layer.

14. The package of claim 7, wherein the backside RDL structure further comprises a second polymer layer on the first polymer layer and the first RDL is on the second polymer layer, and
wherein the tapered portion extends through the second polymer layer and the contact surface contacts the pillar structure at an interface between the first polymer layer and the second polymer layer.

15. The package of claim 6, wherein the pillar structure has a width that is greater than a width of the contact surface and has a thickness greater than 20 μm.

16. A method of forming a package, the method comprising:
forming a backside redistribution layer (RDL) structure comprising:
a first RDL; and
a backside connector extending from a distal side of the first RDL and including a tapered portion having a width that decreases in a direction away from the first RDL, wherein the tapered portion comprises a contact surface at an end of the tapered portion;
attaching a semiconductor die to the backside RDL structure;
forming an encapsulation layer around the semiconductor die on the backside RDL structure; and
forming a frontside RDL structure on the semiconductor die and the encapsulation layer.

17. The method of claim 16, wherein the forming of the backside RDL structure comprises forming the tapered portion to further include a connector plate and tapered sidewalls on the connector plate, such that a thickness of the connector plate is greater than a thickness of the first RDL.

18. The method of claim 17, wherein forming of the backside RDL structure further comprises:
forming a first polymer layer on a distal side of the backside RDL structure, wherein the first RDL is on the first polymer layer;
forming a second polymer layer on the first polymer layer and the first RDL; and
forming a second RDL including a via extending through the second polymer layer and contacting a proximal side of the connector plate.

19. The method of claim 16, wherein the forming of the backside RDL structure comprises forming the backside connector to include a pillar structure connected to the contact surface.

20. A package, comprising:
a frontside redistribution layer (RDL) structure;
a semiconductor die on the frontside RDL structure;
a backside RDL structure on the semiconductor die, comprising:
a first RDL; and
a first polymer layer on the first RDL; and
a backside connector extending from a distal side of the first RDL and including a pillar structure on the surface of the first polymer layer.
